(19) United States
(12) Patent Application Publication
(10) Pub. No.: US 2009/0286331 A2
(43) Pub. Date: Nov. 19, 2009

(54) METHOD FOR SIMULATENOUSLY PRODUCING MULTIPLE WAFERS DURING A SINGLE EPITAXIAL GROWTH RUN AND SEMICONDUCTOR STRUCTURE GROWN THEREBY

(75) Inventors: Vladimir Dmitriev, Gaithersburg, MD (US); Viacheslav Maslennikov, Gaithersburg, MD (US); Vitali Soukhoveev, Gaithersburg, MD (US); Oleg Kovalenkov, Montgomery Village, MD (US)

Correspondence Address: Allan C. Entis Ph.D., Intellectual Property Ltd., 6 Raoul Wallenberg Street, Ramat Hachayal, Tel Aviv, 69719, ISRAEL, 97236488630, 97236488631, mail@entis-ip.com

(73) Assignee: Freiberger Compound Materials GMBH, Freiberg/ Sachsen (DE)

(21) Appl. No.: 12/267,711

(22) Filed: Nov. 10, 2008

Related U.S. Application Data
(63) Continuation of application No. 11/173,193, filed on Jul. 1, 2005, now abandoned.
Application No. 11/173,193 is a continuation-in-part of application No. 10/632,736, filed on Aug. 1, 2003, now Pat. No. 7,279,047.
Application No. 10/632,736 is a continuation of application No. 09/903,299, filed on Jul. 11, 2001, now Pat. No. 6,656,285.
Application No. 09/903,299 is a continuation of application No. 09/900,833, filed on Jul. 6, 2001, now Pat. No. 6,613,143.
(60) Provisional application No. 60/586,707, filed on Jul. 9, 2004.

(51) Int. Cl. H01L 21/205

(52) U.S. Cl. 438/5; 438/483; 257/E21.108

(57) ABSTRACT

HVPE method for simultaneously fabricating multiple Group III nitride semiconductor structures during a single reactor run. A HVPE reactor includes a reactor tube, a growth zone, a heating element and a plurality of gas blocks. A substrate holder is capable of holding multiple substrates and can be a single or multi-level substrate holder. The gas delivery blocks are independently controllable. Gas flows from the delivery blocks are mixed to provide a substantially uniform gas environment within the growth zone. The substrate holder can be controlled, e.g., rotated and/or tilted, for uniform material growth. Multiple Group III nitride semiconductor structures can be grown on each substrate during a single fabrication run of the HVPE reactor. Growth on different substrates is substantially uniform and can be performed on larger area substrates, such as 3-12″ substrates.

### CROSS REFERENCE TO RELATED APPLICATIONS

This application is a continuation of co-pending U.S. application Ser. No. 11/173,193, filed Jul. 1, 2005, which is claims priority under 35 U.S.C. §119 of U.S. Provisional Application No. 60/586,707, filed Jul. 9, 2004, and which is a continuation-in-part of U.S. application Ser. No. 10/632,736, filed Aug. 1, 2003, now U.S. Pat. No. 7,279,047, which is a continuation of U.S. application Ser. No. 09/903,299, filed Jul. 11, 2001, now U.S. Pat. No. 6,656,285, which is a continuation of U.S. application Ser. No. 09/900,833, filed Jul. 6, 2001, now U.S. Pat. No. 6,613,143, the contents of all of which are incorporated herein by reference as though set forth in full, and the priority to all of which being claimed under 35 U.S.C. §§ 119 and 120.

### FIELD OF THE INVENTION

The present invention relates generally to apparatus for processing semiconductor materials and, more particularly, to a HVPE reactor for simultaneously growing multiple uniform Group III nitride semiconductor structures during a single epitaxial growth run.

### BACKGROUND

Group III nitride semiconductor materials, such as GaN, AlN, InN, BN, and their alloys, are perspective materials for the next generation of semiconductor optoelectronic devices including green, blue, violet and ultraviolet light emitting diodes (LEDs) and laser diodes (LDs) and electronic devices including high power, high frequency, high temperature transistors and integrated circuits.

Known methods that are used to fabricate group III nitride devices involve epitaxial growth. Three known epitaxial growth methods that are used to fabricate Group III nitride devices include metal organic chemical vapor deposition (MOCVD) and hydride vapor phase epitaxy (HVPE).

Known MOCVD technologies are capable of growing multiple 2″ wafers in a single epitaxial growth run. For example, certain commercially available MOCVD growth apparatuses are capable of producing 20 2″ epitaxial wafers in the same epitaxial run. Known MOCVD growth apparatuses have also been used to produce Group III nitride epitaxial structures on substrates up to 4″ diameter.

The capabilities of current MOCVD technologies, however, are limited and not particularly useful for efficient and improved fabrication of Group III nitride devices. MOCVD technology for group III nitride materials has several technical limitations. For example, the epitaxial growth rate using MOCVD is relatively low—less than about 10 microns per hour. Consequently, the thicknesses of grown epitaxial layers is limited and thicker layers, such as layers between about 10-20 microns, are not practical. Further, since MOCVD is not suitable to grow thicker layers, the ability of MOCVD technologies to reduce defects is limited because defect density in group III nitride materials is known to decrease substantially with layer thickness. Additionally, MOCVD techniques result in carbon contamination, which is caused by metal organic compounds that are used for MOCVD growth. Further, the size of MOCVD grown epitaxial structures is limited to about a 4-inch diameter due to the non-uniformity of material properties of group III nitride structures that are grown by MOCVD.

It is also known to use HVPE technology to fabricate group III nitride materials. While known HVPE technologies have been successfully utilized to produce low defect epitaxial layers with high growth rates exceeding 100 microns per hour. HVPE is advantageous over MOCVD since materials grown by HVPE are not contaminated with carbon because carbon is not present in the source materials that are used for HVPE technology. Further thick epitaxial layers can be grown by HVPE processes that have reduced defect density relative to MOCVD materials, e.g., a few orders of magnitude less than MOCVD. While HVPE provide certain advantages over MOCVD and has been successfully utilized, HVPE technology can be improved.

One limitation of known HVPE growth techniques is that they are not capable of producing multiple epitaxial wafers of group III nitride materials during a single epitaxial run. Rather, known HVPE techniques utilize multiple runs. Further, the size of known group III nitride epitaxial wafers that are grown by HVPE is limited, thereby resulting in increased material and production costs and reduced yield. A further shortcoming involves the particle contamination of exhaust gases that are produced during HVPE growth of group III nitride materials. Also, certain HVPE techniques grow materials, but aspects of the materials are not uniform. For example, the thickness of layers can vary significantly. This limits the ability to process multiple wafers simultaneously since the wafers will not be uniform.

Accordingly, there exists a need for a HVPE apparatus and method of growing multiple epitaxial wafers of Group III nitride materials during a single epitaxial run. A need also exists for the ability to grow epitaxial wafers on larger area substrates. A further need exists for providing these improvements while maintaining uniformity of growth among different wafers. There also exists a need for an environmental protection device that treats the exhausts of HVPE reactors. Embodiments of the present invention fulfill these needs and provides enhancements over known fabrication systems and methods.

### SUMMARY

One embodiment of the invention is directed to a method of simultaneously fabricating multiple Group III nitride semiconductor structures in a HVPE reactor during a single epitaxial run. The method includes arranging multiple substrates on a substrate holder and positioning a gas supply system within a reactor chamber. A growth zone in the reactor chamber is heated to a growth temperature, and the substrate holder having the multiple substrates is positioned within the growth zone. The method further includes controlling the growth zone temperature, the substrate holder and the plurality of gas delivery blocks so that the substrates on the substrate holder are exposed to a substantially uniform gas environment resulting from mixing gas flows from the gas supply system. A Group III nitride semiconductor structure is grown on each substrate during a single epitaxial run of the HVPE reactor. All of the Group III nitride semiconductor structures that are grown on different substrates are substantially uniform.

In accordance with an alternative embodiment, a method of simultaneously fabricating multiple Group III nitride semiconductor structures in a Hydride Vapor Phase Epitaxy (HVPE) reactor during an epitaxial single run includes arranging multiple substrates on a multi-level substrate holder having an upper level and a lower level and positioning a gas delivery system within a reactor chamber. The gas delivery system includes multiple gas delivery blocks. Each gas delivery block includes a Gallium source tube, an Aluminum source tube, a dopant tube, and an ammonia tube. The method also includes heating a growth zone in the reactor chamber to a growth temperature and positioning the multi-level substrate holder having the substrates in the growth zone. The growth zone temperature, the multi-level substrate holder and the plurality of gas delivery blocks are controlled so that the substrates on the substrate holder are exposed to a substantially uniform gas environment resulting from mixing the gas flows from the plurality of gas delivery blocks. A Group III nitride semiconductor structure is grown on each substrate in the growth zone during a single fabrication run of the HVPE reactor, and all of the Group III nitride semiconductor structures that are grown on different substrates are substantially uniform and have substantially similar thicknesses and chemical compositions.

In various embodiments, with a gas delivery system including gas delivery blocks, each gas delivery block is controlled independently of the other gas delivery blocks. For example, the gas flow in each gas delivery block is controlled independently of the other gas flows from other gas delivery blocks. Further, distances between gas delivery tubes of each gas delivery block and the substrate holder are independently controllable to provide a substantially uniform gas environment within the growth zone.

Various numbers of different-sized substrates can be used. For example, a Group III nitride semiconductor structure being grown on at least eight substrates, each substrate having a diameter of at least two inches. Further, structures can be grown on other large area substrates, including 3-12″ substrates.

A substrate holder can be controlled by rotating and/or tilting the substrate holder. For example, a substrate holder can be tilted an angle of about 1-30 degrees relative to the gas flows from the gas supply system. With multi-level substrate holders, a substrate can be supported by the upper level and face downwardly, and a substrate can be supported by the lower level and face upwardly. Thus, Group III nitride semiconductor structures are grown in opposite directions.

Embodiments of the invention advantageously provide multiple uniform Group III nitride semiconductor structures during a single reactor run. Uniformity can be thickness, chemical composition, dopant concentration, defect densities, and surface roughness. Embodiments provide significant improvements in fabrication of multi-layer wafers for high electron mobility transistor, a blue light emitting diode, an ultraviolet light emitting diode, and a laser diode devices, which can be grown on large area substrates having a diameter greater than 3″ to about 12″ and have one or more GaN, AlN, GaAlN, InN, InGaN, AlInN or AlGaInN layers. Further, growth can be controlled so that a multi-layer wafer includes an intermediate buffer layer between the substrate and a Group III nitride layer.

In another embodiment, Group III nitride semiconductor structures are simultaneously fabricated on different substrates during a single epitaxial run of a Hydride Vapor Phase Epitaxy (HVPE) reactor, and all of the structures that were fabricated during the single epitaxial run are substantially uniform. Embodiments of the invention advantageously provide multiple uniform Group III nitride semiconductor structures during a single reactor run. Uniformity can be thickness, chemical composition, dopant concentration, defect densities, and surface roughness to provide improvements over known Group III nitride materials and devices.

### BRIEF DESCRIPTION OF THE DRAWINGS

FIG. 1 is a schematic illustration of a horizontal furnace;

FIG. 2 is an illustration of one embodiment of a boat suitable for use with the furnace shown in FIG. 1;

FIG. 3 is an illustration of an individual source tube and a means of varying the source contained within the tube relative to the reactor;

FIG. 4 is a block diagram outlining the preferred method of fabricating bulk GaN;

FIG. 5 is a schematic illustration of an alternate embodiment for use in growing AlGaN;

FIG. 6 is a block diagram outlining the preferred method of fabricating bulk AlGaN;

FIG. 7 is a schematic illustration of an alternate embodiment for use in growing doped material;

FIG. 8 outlines a process used in at least one embodiment to grow material with a matching seed crystal;

FIG. 9 illustrates a reactor for simultaneously epitaxially growing multiple Group III nitride semiconductor materials and devices according to one embodiment of the invention.

FIG. 10 illustrates a square base or substrate holder for supporting seven substrates for use with various embodiments;

FIG. 11 illustrates a circular base or substrate holder for supporting 14 substrates for use with various embodiments;

FIG. 12 generally illustrates gas delivery blocks for providing a substantially uniform gas environment within a growth zone of a HVPE reactor according to one embodiment;

FIG. 13 illustrates gas delivery blocks shown in FIG. 12 in further detail;

FIG. 14 illustrates gas flows from gas delivery blocks to the substrate holder supporting multiple substrates as shown in FIG. 11;

FIG. 15 illustrates a substrate holder that can support multiple substrates and that is tiltable and rotatable;

FIG. 16 illustrates a multi-level substrate holder supporting multiple face-up substrates according to one embodiment;

FIG. 17 illustrates a multi-level substrate holder for supporting face-down and face-up substrates according to another embodiment;

FIG. 18 illustrates gas flows from gas delivery blocks to a substrate holder supporting multiple substrates that face opposite directions;

FIG. 19 illustrates a Group III nitride semiconductor material that is grown on a large area four inch or larger diameter substrate according to one embodiment;

FIG. 20 generally illustrates a multi-layer device structure grown on a thick Group III nitride semiconductor material that is grown on a large area four inch or larger diameter substrate according to one embodiment;

FIG. 21 generally illustrates a Group III nitride structure having an intermediate layers for a multi-layer device according to a further embodiment;

FIG. 22 illustrates another example of a Group III nitride device structure having multiple intermediate layers according to another alternative embodiment;

FIG. 23 illustrates a substrate holder supporting a convex substrate for use with various embodiments of the invention;

FIG. 24 illustrates a convex Group III nitride semiconductor structure that is formed using the convex substrate shown in FIG. 23;

FIG. 25 is a chart summarizing test results of growing seven 2″ GaN samples during a single epitaxial run and showing the uniformity of different samples grown at the same time during a single run;

FIG. 26 is a chart summarizing test results of growing seven 2″ Si-doped GaN samples during a single epitaxial run and showing the uniformity of different samples grown at the same time during a single run; and

### DESCRIPTION OF THE SPECIFIC EMBODIMENTS

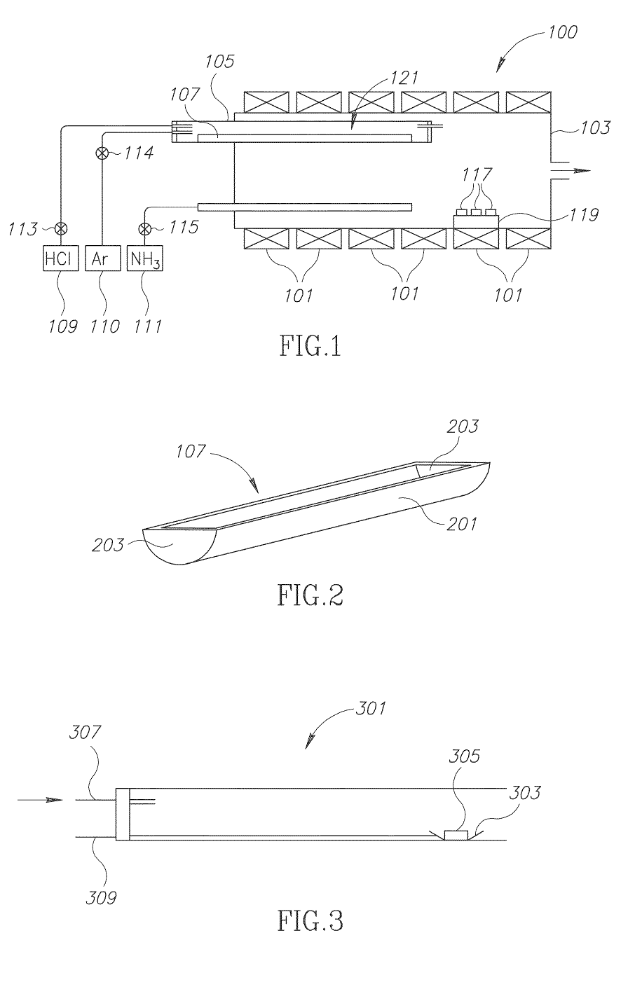

One embodiment provides a method and apparatus for growing bulk gallium nitride (GaN) or aluminum gallium nitride (AlGaN), preferably using a modified hydride vapor phase epitaxial (HVPE) approach. FIG. 1 is a schematic illustration of a horizontal furnace. It is understood that embodiments are not limited to this particular furnace configuration as other configurations (e.g., vertical furnaces) that offer the required control over the temperature, temperature zone or zones, gas flow, source and substrate location, source configuration, etc., can also be used. The furnace configuration illustrated in FIG. 1 is preferred for the growth of undoped GaN as it easily accommodates the desired gallium source.

Furnace 100 is comprised of multiple temperature zones, preferably obtained through the use of multiple heaters 101, each of which at least partially surrounds reactor chamber or tube 103 (generally chamber). In one embodiment, a six zone configuration is used in which heaters 101 are resistive heaters. It is understood that although reactor chamber 103 preferably has a cylindrical cross-section, other configurations can be used such as a “tube” with a rectangular cross-section. Within reactor chamber 103 are one or more source tubes 105. As noted with respect to reactor chamber 103, although source tubes 105 preferably have a cylindrical cross-section, the invention is not limited to cylindrical source tubes.

In order to grow undoped bulk GaN, a single source tube 105 is required. Within source tube 105 is a source boat 107. As used herein, the term “boat” simply refers to a means of holding the source material. For example, boat 107 may be comprised of a portion of a tube 201 with a pair of end portions 203 as illustrated in FIG. 2. Alternately, the source material can be held within source tube 105 without the use of a separate boat 107. Alternate boat configurations are clearly envisioned by the inventors.

As described in detail below, in one embodiment, the desired growth temperature depends upon the stage of crystal growth (e.g., crystal nucleation versus high growth rate). The temperature of a source in general, and the temperature of a specific portion of the gallium source in particular, are preferably controlled by varying the heat applied by specific heaters 101. Additionally, in one embodiment in which multiple source types are used, the location of a particular source (e.g., an impurity source) relative to reactor chamber 103 can be controllably varied, typically by altering the position of the source. For example, as illustrated in FIG. 3, a source tube 301 typically includes a boat 303, a source 305 within boat 303, and a gas inlet 307. A control rod 309 coupled to boat 303 can be used to alter the position of the boat, and thus the source, within the reactor. Control rod 309 can be manually manipulated, as provided for in the illustrated configuration, or coupled to a robotic positioning system (not shown).

In one embodiment, coupled to each source tube are one or more sources of gas 109-111. The rate of gas flow through a particular source tube is controlled via valves 113-115, either manually or by an automatic processing system.

A substrate 117 is located on a pedestal or substrate holder 119 within the growth zone of reactor 103. Although typically multiple substrates 117 are manually loaded into the reactor for co-processing, a single substrate can be processed with the invention. Additionally, substrates 117 can be automatically positioned within the furnace for automated production runs. To vary the growth zone temperature, and thus substrate or substrates 117, either the position of the substrates relative to reactor 103 are changed or the amount of heat applied by heaters 101 proximate to the growth zone is varied.

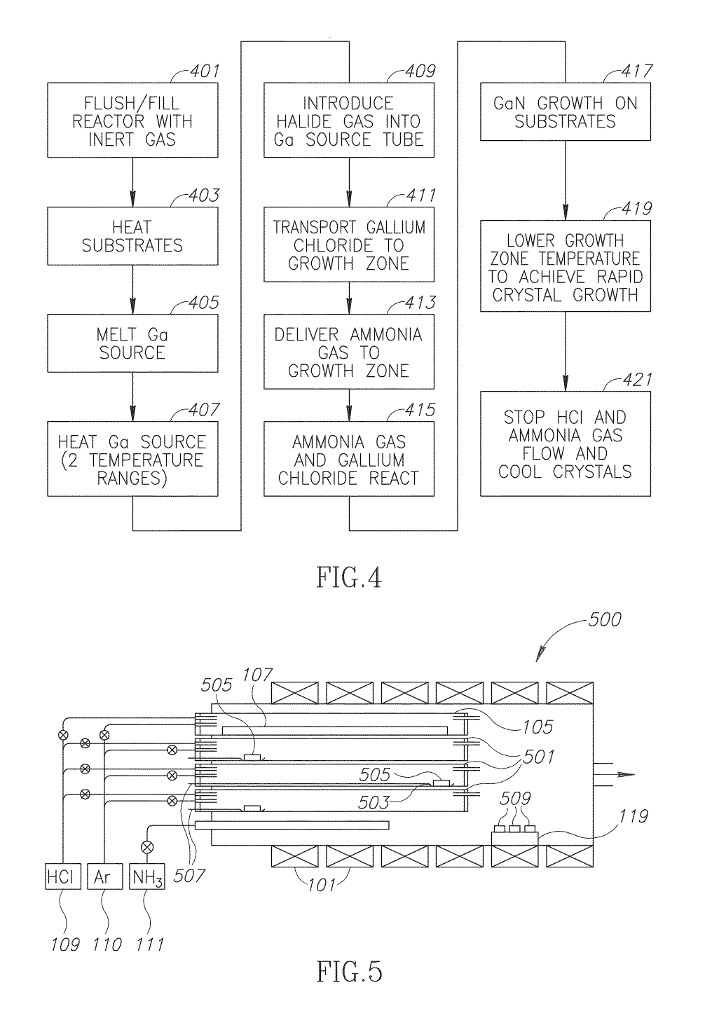

FIGS. 1 and 4 illustrate a specific reactor 100 and the steps used to grow bulk GaN, respectively. Although reactor 100 is a hot-wall, horizontal reactor and the process is carried out in an inert gas flow at atmospheric pressure, as previously noted other reactor configurations can be used to perform the modified HVPE process. Preferably source tube 105 and source boat 107 are comprised of quartz. Other materials can be used for boat 107, however, such as sapphire or silicon carbide. Within boat 107, or simply within tube 105 if no separate boat is used, is a Ga metal source 121.

In order to achieve extended GaN growth, as required to grow bulk GaN, the inventors have found that an extended source of Ga must be used and that the extended source must be maintained at more than one temperature. Specifically, Ga metal 121 is positioned relative to reactor 103 such that a large quantity of source 121 (i.e., preferably greater than 50 percent of source 121, and more preferably greater than 90 percent of source 121 at reaction initiation) is maintained at a relatively low temperature, preferably less than 100° C. and more than the melting temperature of Ga (i.e., 29.78° C.), and more preferably within the temperature range of 30° C. to 40° C. Due to the low temperature, this portion of Ga source 121 has limited reaction with the halide reactive gas coupled to and flowing through source tube 105. If desired, a portion of source tube 105 and Ga source 121 are maintained outside of the reactor volume as illustrated in FIG. 1. Alternately, the lower temperature of this portion of source 121 is achieved through control of heaters 101 adjacent to the lower temperature portion of the source.

At the high temperature end of source tube 105, the temperature of Ga source 121 is held at a relatively high temperature, typically between 450° C. and 850° C. and preferably at a temperature of approximately 650° C. During crystal growth, a constant source of Ga is maintained due to the flow of Ga from the low temperature portion of tube 105 to the higher temperature portion of tube 105. Accordingly, by providing a large Ga source, embodiments allow the growth of bulk GaN while limiting the amount of the source that reacts with the halide reactive gas. It is understood that although one embodiment utilizes a modified HVPE process in conjunction with the large Ga source described above, the source can be used with other bulk growth techniques (e.g., sublimation techniques).

In order to grow bulk GaN according to one embodiment, a source of halide gas 109, preferably HCl, is coupled to source tube 105 along with a source of inert gas 110, preferably Ar. A source of ammonia gas 111 is also coupled to reactor 103. In order to grow bulk GaN, preferably seed crystals 117 are comprised of GaN, thus providing a lattice and coefficient of thermal expansion match between the seed and the material to be grown. As a result of using GaN seed crystals, improved quality in the as-grown material is achieved. Alternately, seed crystals 117 can be of silicon carbide (SiC), sapphire, gallium arsenide (GaAs), or other material. Seed crystal pedestal 119 is preferably fabricated from quartz, although other materials such as silicon carbide or graphite can also be used.

Initially reactor 103 is flushed and filled with an inert gas, preferably Ar, from gas source 110 (step 401). The inert gas can enter the reactor through source tube 105, thereby flushing the source tube, through a separate entry line (not shown), or both. The flow of inert gas is controlled by metering valve 114 and is typically in the range of 1 to 25 liters per minute. Substrates (or substrate) 117 are then heated to the desired growth temperature (step 403). In one embodiment, the growth zone, and thus the substrates within the growth zone, are heated to a temperature within the range of 1,000° C. and 1,100° C. This temperature achieves a higher quality material in the as-grown crystal, but yields relatively slow growth rate. In an alternate embodiment, the growth zone is maintained at a temperature within the range of 850° C. and 1,000° C. Although this temperature is capable of fast crystal growth, the resulting crystal is of lower quality. In the preferred embodiment of the invention, the methodology of which is illustrated in FIG. 4, the growth zone and thus the substrates (or substrate) within the growth zone are initially heated to a high temperature within the range of 1,000° C. and 1,100° C., thus initiating high quality crystal growth. Once crystal growth has been initiated, the source temperature is lowered and maintained at a temperature within the range of 850° and 1,000° C., thus allowing rapid crystal growth to be achieved. Preferably the period of high quality crystal growth is at least 10 minutes and the period of rapid crystal growth is at least 12 hours. More preferably the period of high quality crystal growth is at least 30 minutes and the period of rapid crystal growth is at least 24 hours.

Preferably prior to initiating crystal growth, the surfaces of substrates 117 are etched to remove residual surface contamination, for example by using gaseous HCl from supply 109. The Ga source material 121 is initially heated to a temperature sufficient to cause the entire source to melt (step 405). As previously noted, the melting temperature of Ga is 29.78° C. and source 121 is preferably heated to a temperature within the range of 30° C. to 40° C. A portion of source tube 105 closest to substrates 117, and thus the portion of source material 121 closest to substrates 117, is heated to a relatively high temperature (step 407), typically between 450° C. and 850° C. and preferably at a temperature of approximately 650° C.

After the source material is heated a halide reactive gas, preferably HCl, is introduced into source tube 105 (step 409). As a result of the reaction between HCl and Ga, gallium chloride is formed which is transported to the reactor's growth zone by the flow of the inert (e.g., Ar) gas (step 411). Simultaneously, ammonia gas (NH₃) from source 111 is delivered to the growth zone (step 413). The NH₃ gas and the gallium chloride gas react (step 415) to form GaN on the surface of seed substrates 117 (step 417). The initial growth rate of the GaN is in the range of 0.05 to 1 micron per minute. After a high quality GaN layer of sufficient thickness has been grown, typically on the order of 20 microns and preferably on the order of 50 microns, the temperature of the growth zone is lowered (step 419) to a temperature within the range of 850° C. and 1,000° C., thereby allowing GaN to be grown at an accelerated rate (i.e., in the range of 5 to 500 microns per hour). After the desired boule thickness has been achieved, the flow of HCl and NH₃ gas is stopped and substrates 117 are cooled in the flowing inert gas (step 421). Depending on gas flows through Ga and Al source tubes, AlGaN alloy composition may be varied from 0 to 100 mol. % of AlN.

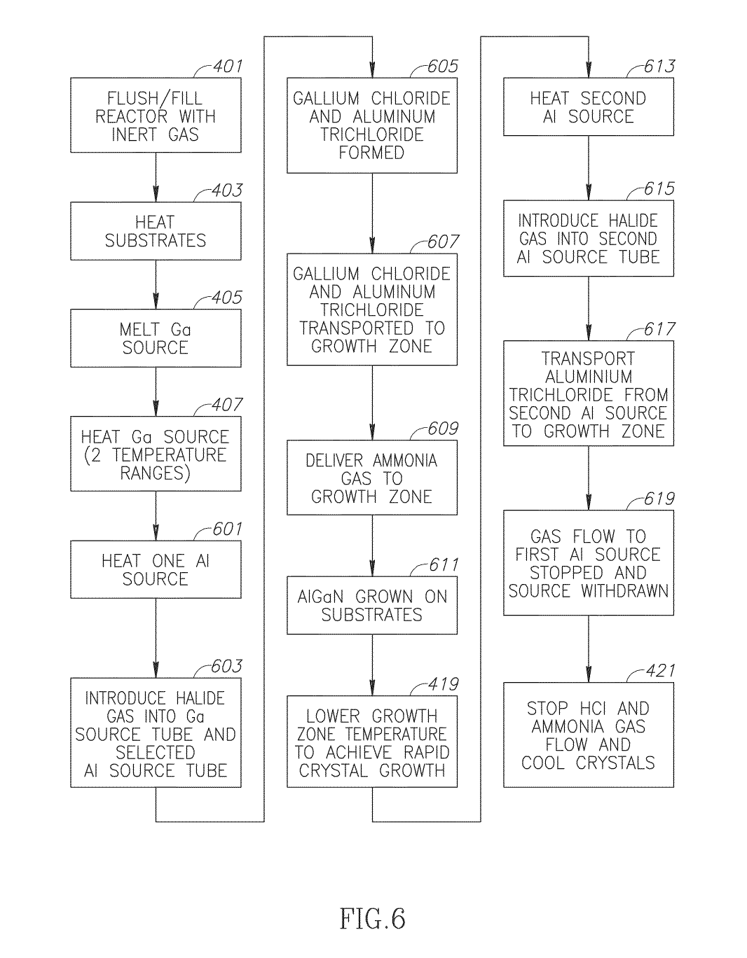

FIGS. 5 and 6 illustrate another embodiment that can be used to grow AlGaN boules. Reactor 500 is substantially the same as reactor 100 except for the inclusion of an aluminum (Al) source. Also in this embodiment, Ga source tube 105 is shown to be completely within the reactor. As the Al source tends to degrade over time due to the reaction between the Al and the source tube/boat materials, in one embodiment, reactor 500 includes multiple Al sources. As shown, reactor 500 includes three Al source tubes 501, although it is understood that fewer or greater numbers of Al source tubes can be included, depending upon the quantity of AlGaN to be grown. Within each Al source tube 501 is a source boat 503 containing a quantity of Al metal 505. Preferably each source boat 503 is fabricated from sapphire or silicon carbide. Additionally, as discussed with reference to FIG. 3, the position of each source boat 503 within the reactor can be altered using either a manual or automatic control rod 507.

As previously noted, preferably the seed crystal is of the same material as the crystal to be grown. Therefore in order to grow bulk AlGaN, preferably seed crystal 609 is fabricated of AlGaN. Alternately, seed crystal 609 can be of GaN, SiC, sapphire, GaAs, or other material.

The methodology to grow AlGaN is very similar to that outlined in FIG. 4 for GaN growth. In this embodiment, during source heating one of the Al sources 505 is heated to a temperature of preferably between 700° C. and 850° C. (step 601), the selected Al source being appropriately positioned within the reactor to achieve the desired temperature. Once all of the materials have achieved the desired growth temperature, halide gas (e.g., HCl) is introduced into Ga source tube 105 and the selected Al source tube (step 603). As a result, gallium chloride and aluminum trichloride are formed (step 605). Both the gallium chloride and aluminum chloride are transported to the growth zone using an inert gas (e.g., Ar) (step 607). NH₃ gas 111 is simultaneously introduced into the growth zone with the source materials (step 609) resulting in a reaction by the three gases to form AlGaN (step 611). As in the prior embodiment, preferably the growth zone is initially held at a higher temperature in order to initiate the growth of high quality material. Once a sufficiently large layer is formed, preferably on the order of 50 microns thick, the temperature of the growth zone is lowered (step 419) to a temperature within the range of 850° C. and 1,000° C. in order to achieve accelerated growth. Prior to exhaustion or excessive degradation of the initially selected Al source, a second Al source 503 is heated to a temperature within the preferred range of 700° C. and 850° C. (step 613). Once the second Al source is heated, halide gas (e.g., HCl) is introduced into the second Al source tube (step 615) and the resultant aluminum trichloride is transported to the growth zone (step 617). The flow of halide and inert gas through the initially selected Al source tube is stopped and the first Al source is withdrawn from the high temperature zone (step 619). The process of introducing new Al sources continues as long as necessary to grow the desired AlGaN boule. After the desired boule thickness has been achieved, the flow of HCl and NH₃ gas is stopped and substrates 117 are cooled in flowing inert gas (step 421).

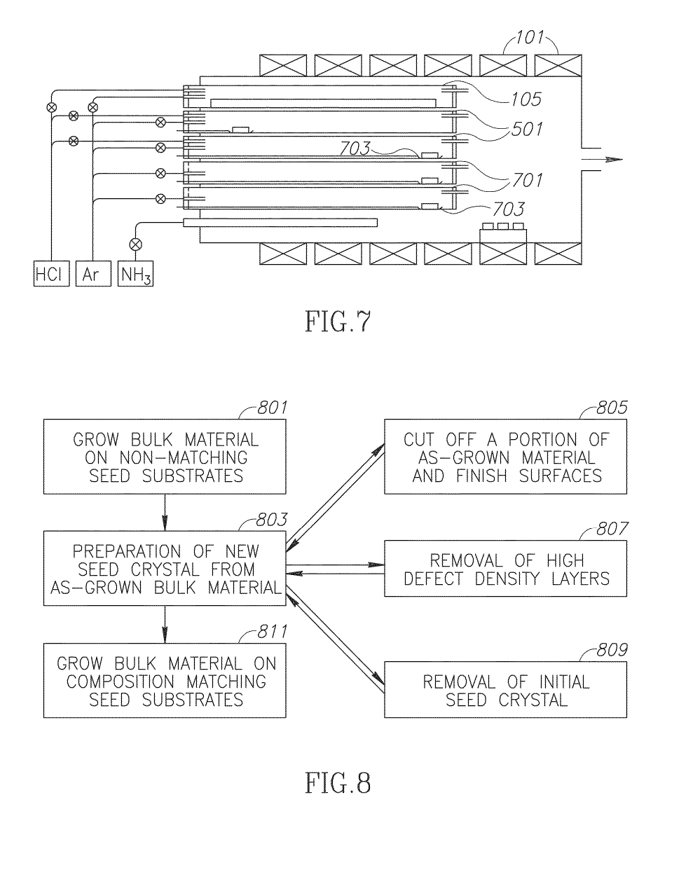

Embodiments can be used to grow GaN or AlGaN of various conductivities, the conductivity dependent upon the dopants added during crystal growth. FIG. 7 illustrates another embodiment that allows the addition of dopants during crystal growth. The embodiment shown includes Ga source tube 105, two Al source tubes 501, and two dopant source tubes 701. It is understood that the number of source tubes is based on the number of constituents required for the desired crystal.

To grow p-type GaN or AlGaN, a suitable dopant (i.e., acceptor) is placed within one or more boats 703 within one or more dopant source tubes 701, thus allowing the desired dopants to be added to the crystal during growth. Preferably either magnesium (Mg) or a combination of Mg and zinc (Zn) is used. If multiple dopants are used, for example both Mg and Zn, the dopants may be in the form of an alloy, and thus be located within a single boat, or they may be in the form of individual materials, and thus preferably located within separate boats. To grow insulating (i.e., i-type) GaN or AlGaN, preferably Zn is used as the dopant. Although undoped GaN and AlGaN exhibit low n-type conductivity, controllable n-type conductivity can be achieved by doping the growing crystal with donors. Preferred donors include silicon (Si), germanium (Ge), tin (Sn), and oxygen (O).

A detailed discussion of GaN and AlGaN doping is provided in U.S. application Ser. No. 09/861,011, now U.S. Pat. No. 6,555,452, pages 7-14, the teachings of which are hereby incorporated by reference for any and all purposes. In one embodiment, dopant source boats 703 are formed of non-reactive materials (e.g., sapphire), extremely pure source materials are used (e.g., 99.999 to 99.9999 purity Mg), and the source materials are etched prior to initiating the growth process to insure minimal surface contamination. Although the temperature for a particular dopant source depends upon the selected material, typically the temperature is within the range of 250° C. to 1050° C. If a Mg dopant is used, preferably the temperature is within the range of 450° C. to 700° C., more preferably within the range of 550° C. to 650° C., and still more preferably at a temperature of approximately 615° C. The dopant source or sources are heated simultaneously with the substrate and the Ga or the Ga and Al sources. The dopants are delivered to the growth zone via inert gas (e.g., Ar) flow. The flow rate depends upon the conductivity to be achieved in the growing crystal. For example, for growth of p-type GaN or AlGaN, the flow rate for a Mg dopant is typically between 1,000 and 4,000 standard cubic centimeters per minute, and preferably between 2,000 and 3,500 standard cubic centimeters per minute.

As previously described, the level of doping controls the conductivity of the grown material. In order to achieve p-type material, it is necessary for the acceptor concentration (Nₐ) to be greater than the donor concentration (N_{d}). The inventors have found that in order to achieve the desired Nₐ/N_{d} ratio and grow p-type GaN or AlGaN, the concentration of the acceptor impurity must be in the range of 10¹⁸ to 10²¹ atoms per cubic centimeter, and more preferably in the range of 10¹⁹ to 10²⁰ atoms per cubic centimeter. For an i-type layer, the doping level must be decreased, typically such that the dopant concentration does not exceed 10¹⁹ atoms per cubic centimeter.

As previously noted, improved crystal quality in the as-grown material is achieved when the seed crystal and the material to be grown are of the same chemical composition so that there is no crystal lattice or coefficient of thermal expansion mismatch. Accordingly, FIG. 8 outlines a process used in at least one embodiment in which material is grown using a matching seed crystal.

In the illustrated embodiment, initially material (e.g., doped or undoped GaN or AlGaN) is grown from a seed crystal of different chemical composition using the techniques described in detail above (step 801). As previously noted, the seed crystal can be of sapphire, silicon carbide, GaAs, or other material. After the bulk material is formed, a portion of the grown crystal is removed from the bulk for use as a new seed crystal (step 803). For example, new seed crystals can be obtained by cutting off a portion of the as-grown bulk (step 805) and subjecting the surfaces of the cut-off portion to suitable surface preparatory steps (step 807). Alternately, prior to cutting up the as-grown bulk material, the initial seed crystal can be removed (step 809), for example using an etching technique. Once a new seed crystal is prepared, the bulk growth process of the present invention is used to grow a second crystal (step 811). However, as a consequence of the ability to grow bulk materials according to the invention, the second growth cycle is able to utilize a seed crystal of the same composition as the material to be grown, thus yielding a superior quality material.

### SPECIFIC EMBODIMENTS

### Embodiment 1

According to this embodiment, the modified HVPE process described above was used to grow thick GaN layers on SiC substrates. Suitable GaN substrates were then fabricated and used in conjunction with the modified HVPE process of the invention to grow a GaN single crystal boule. The second GaN boule was cut into wafers suitable for device applications.

In this embodiment, multiple SiC substrates of a 6H polytype were loaded into the growth zone of a reactor similar to that shown in FIG. 1. The substrates were placed on a quartz sample holder with the (0001) Si on-axis surface positioned for GaN deposition. One kilogram of Ga metal was positioned in the source boat within the Ga source tube. After purging the reactor with Ar gas to remove air, the growth zone and the Ga source zone were heated to 1100° C. and 650° C., respectively. The majority of the Ga source, however, was maintained at a temperature of less than 100° C., typically in the range of 30° C. to 40° C. To prepare the substrates for GaN deposition, HCl gas was introduced into the growth zone to etch the SiC substrates. The HCl gas was then introduced into the Ga source zone, thereby forming gallium chloride that was transported into the growth zone by the Ar carrier gas. Simultaneously, NH₃ gas was introduced into the growth zone, the NH₃ gas providing a source of nitrogen. As a result of the reaction between the gallium chloride and the NH₃ gases, a GaN layer was grown on the SiC surface. The NH₃ and gallium chloride gases were expelled from the reactor by the flow of the Ar gas. After allowing the growth process to continue for a period of 24 hours, the flow of HCl and NH₃ gases was stopped and the furnace was slowly cooled down to room temperature with Ar gas flowing through all of the gas channels. The reactor was then opened to the air and the sample holder was removed. As a result of this growth process, GaN layers ranging from 0.3 to 2 millimeters were grown on SiC substrates. The range of GaN thicknesses resulted from the distribution of GaN growth rates within the growth zone.

To prepare GaN seed substrates, the SiC substrates were removed from the grown GaN material by chemically etching the material in molten KOH. The etching was carried out in a nickel crucible at a temperature within the range of 450° C. to 650° C. Prior to beginning the etching process, the molten KOH was maintained at the etching temperature for several hours to remove the moisture from the melt and the crucible. Once the substrates were placed within the molten KOH, only a few hours were required to etch away most of the SiC substrates from the grown GaN. This process for substrate removal is favored over either mechanical or laser induced substrate removal. The remaining SiC substrate was removed by reactive ion etching in a Si₃F/Ar gas mixture. For some of the as-grown material, polycrystalline material was noted in the peripheral regions, this material being subsequently removed by grinding. Additionally, in some instances the surface of the as-grown material required mechanical polishing to smooth the surface. In these instances, after the polishing was completed, reactive ion etching or chemical etching was used to remove the thin surface layer damaged during polishing. As a result of this procedure, the desired GaN seeds were obtained. The high quality of the resultant material was verified by the x-ray rocking .omega.-scan curves (e.g., 300 arc sec for the full width at half maximum (FWHM) for the (0002) GaN reflection). X-ray diffraction measurements showed that the as-grown material was 2H-GaN.

The inventors have found that SiC substrates are preferable over sapphire substrates during the initial growth process as the resultant material has a defined polarity. Specifically, the resultant material has a mixture of gallium (Ga) polarity and nitrogen (N) polarity. The side of the as-grown material adjacent to the SiC substrates has an N polarity while the opposite, outermost layer of the material has a Ga polarity.

Prior to growing a GaN boule utilizing the process of the invention, in some instances the inventors found that it was beneficial to grow a thin GaN layer, e.g., typically in the range of 10 to 100 microns thick, on one or both sides of the GaN substrates grown above. The additional material improved the mechanical strength of the substrates and, in general, prepared the GaN surface for bulk growth. Prior to bulk growth, the GaN seed substrates were approximately 1 millimeter thick and approximately 6 centimeters in diameter.

The growth of the GaN boule used the same reactor as that used to grow the GaN seed substrates. The substrates were positioned within the reactor such that the new material would be grown on the (0001) Ga on-axis face. The inventors have found that the Ga face is preferred over the N face as the resulting boule has better crystal properties and lower dislocation density. It should be noted that the (0001) surface can be tilted to a specific crystallographic direction (e.g., [11-20] and that the tilt angle may be varied between 0.5 and 90 degrees. In the present embodiment, the tilt angle was zero.

In addition to loading the seed substrates into the growth zone of the reactor, two kilograms of Ga was loaded into the source boat within the Ga source tube. After purging the reactor with Ar gas, the growth zone and the Ga source zone were heated to 1050° C. and 650° C., respectively. As previously described, only a small portion of the Ga source was brought up to the high source temperature noted above (i.e., 650° C.). Most of the Ga source was maintained at a temperature close to room temperature, typically in the range of 30° C. and 40° C. Prior to initiating GaN growth, a mixture of NH₃ and HCl gas was introduced in the growth zone to refresh the GaN seed surface. As in the growth of the seed crystal previously described, HCl was introduced into the Ga source zone to form gallium chloride that was then transported to the growth zone with Ar gas. At the same time, NH₃ gas used as a source of nitrogen was introduced into the growth zone. The GaN was formed by the reaction between the gallium chloride and the NH₃ gases.

After approximately 30 minutes of GaN growth, the GaN substrate was moved into a second growth zone maintained at a temperature of approximately 980° C., thereby achieving accelerated growth rates as previously disclosed. This process was allowed to continue for approximately 80 hours. After that, HCl flow through the Ga source tube and NH₃ flow though the growth zone were stopped. The furnace was slow cooled down to room temperature with Ar flowing through all gas channels. The reactor was then opened to the air and the sample holder was removed from the reactor. The resultant boule had a diameter of approximately 6 centimeters and a thickness of approximately 1 centimeter. The crystal had a single crystal 2H polytype structure as shown by x-ray diffraction measurements.

After growth, the boule was machined to a perfect cylindrical shape with a 5.08 centimeter diameter (i.e., 2 inch diameter), thereby removing defective peripheral areas. One side of the boule was ground to indicate the (11-20) face. Then the boule was sliced into 19 wafers using a horizontal diamond wire saw with an approximately 200 micron diamond wire. Before slicing, the boule was oriented using an x-ray technique in order to slice the wafers with the (0001) oriented surface. The slicing rate was about 1 millimeter per minute. The wire was rocked around the boule during the slicing. Thickness of the wafers was varied from 150 microns to 500 microns. Wafer thickness uniformity was better than 5 percent.

After slicing, the wafers were polished using diamond abrasive suspensions. Some wafers were polished only on the Ga face, some wafers were polished only on the N face, and some wafers were polished on both sides. The final surface treatment was performed using a reactive ion etching technique and/or a chemical etching technique to remove the surface layer damaged by the mechanical treatment. The surface of the wafers had a single crystal structure as shown by high energy electron diffraction techniques. The surface of the finished GaN wafers had a mean square roughness, RMS, of 2 nanometers or less as determined by atomic force microscopy utilizing a viewing area of 5 by 5 microns. The defect density was measured using wet chemical etching in hot acid. For different wafers, etch pit density ranged from 10 to 1000 per square centimeter. Some GaN wafers were subjected to heat treatment in an argon atmosphere in a temperature range from 450° C. to 1020° C. in order to reduce residual stress. Raman scattering measurements showed that such heat treatment reduced stress from 20 to 50%.

In order to compare the performance of devices fabricated using the GaN substrates fabricated above to those fabricated on SiC and sapphire, GaN homoepitaxial layers and pn diode multi-layer structures were grown. Device structures included AlGaN/GaN structures. Prior to device fabrication, surface contamination of the growth surface of the GaN wafers was removed in a side growth reactor with a NH—HCl gas mixture. The thickness of individual layers varied from 0.002 micron to 200 microns, depending upon device structure. For example, high frequency device structures (e.g., heterojunction field effect transistors) had layers ranging from 0.002 to 5 microns. For high power rectifying diodes, layers ranged from 1 to 200 microns. In order to obtain p-type layers, a Mg impurity was used while n-type doping was obtained using a Si impurity. The fabricated device structures were fabricated employing contact metallization, photolithography and mesa insulation.

The structures fabricated on the GaN wafers were studied using optical and electron microscopy, secondary ion mass spectrometry, capacitance-voltage and current-voltage methods. The devices showed superior characteristics compared with devices fabricated on SiC and sapphire substrates. Additionally, it was shown that wafer surface cleaning procedure in the reactor reduced defect density, including dislocation and crack density, in the grown epitaxial layers.

### Embodiment 2

In this embodiment, a GaN seed was first fabricated as described in Embodiment 1. The 5.08 centimeter diameter (i.e., 2 inch diameter) prepared GaN seed substrates were then placed within a stainless steel, resistively heated furnace and a GaN single crystal boule was grown using a sublimation technique. GaN powder, located within a graphite boat, was used as the Ga vapor source while NH₃ gas was used as the nitrogen source. The GaN seed was kept at a temperature of 1100° C. during the growth. The GaN source was located below the seed at a temperature higher than the seed temperature. The growth was performed at a reduced pressure.

The growth rate using the above-described sublimation technique was approximately 0.5 millimeters per hour. After a growth cycle of 24 hours, a 12 millimeter thick boule was grown with a maximum boule diameter of 54 millimeters. The boule was divided into 30 wafers using a diamond wire saw and the slicing and processing procedures described in Embodiment 1. X-ray characterization was used to show that the GaN wafers were single crystals.

### Embodiment 3

In this embodiment, bulk GaN material was grown in an inert gas flow at atmospheric pressure utilizing the hot-wall, horizontal reactor described in Embodiment 1. Six 5.08 centimeter diameter (i.e., 2 inch diameter) silicon carbide substrates of a 6H polytype, were placed on a quartz pedestal and loaded into a growth zone of the quartz reactor. The substrates were located such that the (0001) Si on-axis surfaces were positioned for GaN deposition. Approximately 0.9 kilograms of Ga (7N) was located within a quartz boat in the Ga source zone of the reactor. This channel was used for delivery of gallium chloride to the growth zone of the reactor. A second quartz tube was used for ammonia (NH₃) delivery to the growth zone. A third separate quartz tube was used for HCl gas delivery to the growth zone.

The reactor was filled with Ar gas, the Ar gas flow through the reactor being in the range of 1 to 25 liters per minute. The substrates were then heated in Ar flow to a temperature of 1050° C. and the hot portion of the metal Ga source was heated to a temperature in the range of 350° C. to 800° C. The lower temperature portion of the Ga source was maintained at a temperature within the range of 30° C. to 40° C. HCl gas was introduced into the growth zone through the HCl channel. As a result, the SiC seed substrates were etched at Ar—HCl ambient before initiating the growth procedure.

To begin the growth process, HCl gas was introduced into the Ga source zone, creating gallium chloride that was delivered to the growth zone by Ar gas flow. Simultaneously, NH₃ was introduced into the growth zone. As a result of the reaction between the gallium chloride gas and the ammonia gas, a single crystal epitaxial GaN layer was grown on the substrates. The substrate temperature during the growth process was held constant at 1020° C. After a growth period of 20 hours, the flow of HCl and NH₃ were stopped and the samples were cooled in flowing Ar.

As a result of the growth process, six GaN/SiC samples were obtained in which the GaN thickness was in the range of 1 to 3 millimeters. To remove the SiC substrates, the samples were first glued to metal holders using mounting wax (e.g., QuickStick™ 135) at a temperature of 130° C. with the GaN layer facing the holder. The holders were placed on a polishing machine (e.g., SBT Model 920) and a thick portion of the SiC substrates were ground away using a 30 micron diamond suspension at 100 rpm with a pressure of 0.1 to 3 kilograms per square centimeter. This process was continued for a period of between 8 and 24 hours. After removal of between 200 and 250 microns of SiC, the samples were unglued from the holders and cleaned in hot acetone for approximately 20 minutes.

The residual SiC material was removed from each sample using a reactive ion etching (RIE) technique. Each sample was placed inside a quartz etching chamber on the stainless steel holder. The RIE was performed using Si₃F/Ar for a period of between 5 and 12 hours, depending upon the thickness of the residual SiC. The etching rate of SiC in this process is about 10 microns per hour. After the RIE process was completed, the samples were cleaned to remove possible surface contamination. As a result of the above processes, freestanding GaN plates completely free of any trace of SiC were obtained.

After completion of a conventional cleaning procedure, the GaN plates were placed in the HVPE reactor. A GaN homoepitaxial growth was started on the as-grown (0001) Ga surface of the GaN plates. The growth temperature was approximately 1060° C. After a period of growth of 10 minutes, the samples were cooled and unloaded from the reactor. The GaN layer grown on the GaN plates was intended to cover defects existing in the GaN plates. Thus, samples at the completion of this step were comprised of 5.08 centimeter diameter (i.e., 2 inch diameter) GaN plates with approximately 10 microns of newly grown GaN. Note that for some samples a GaN layer was grown not only on the (0001) Ga face of the GaN plates, but also on the (0001) N face of the plates. Peripheral highly defective regions of the GaN plates were removed by grinding.

Three of the GaN plates from the previous process were loaded into the reactor in order to grow thick GaN boules. Gallium chloride and ammonia gas served as source materials for growth as previously disclosed. In addition, during the growth cycle the GaN boules were doped with silicon supplied to the growth zone by S₂H₄ gas. Growth temperatures ranged from 970° C. to 1020° C. and the growth run lasted for 48 hours. Three boules with thicknesses of 5 millimeters, 7 millimeters, and 9 millimeters, respectively, were grown.

The boules were sliced into GaN wafers. Prior to wafer preparation, some of the boules were ground into a cylindrical shape and peripheral polycrystalline GaN regions, usually between 1 and 2 millimeters thick, were removed. Depending upon wafer thickness, which ranged from 150 to 500 microns, between 7 and 21 wafers were obtained per boule. The wafers were then polished on either one side or both sides using an SBT Model 920 polishing machine with a 15 micron diamond suspension at 100 rpm with a pressure of between 0.5 and 3 kilograms per square centimeter for 9 minutes per side. After cleaning all parts and the holder for 5 to 10 minutes in water with soap, the polishing process was repeated with a 5 micron diamond suspension for 10 minutes at the same pressure. After subjecting the parts and the holder to another cleaning, the wafers were polished using a new polishing cloth and a 0.1 micron diamond suspension for an hour at 100 rpm with a pressure of between 0.5 and 3 kilograms per square centimeter.

After cleaning, the GaN wafers were characterized in terms of crystal structure, electrical and optical properties. X-ray diffraction showed that the wafers were single crystal GaN with a 2H polytype structure. The FWHM of the x-ray rocking curve measured in Ω-scanning geometry ranged from 60 to 360 arc seconds for different samples. After chemical etching, the etch pit density measured between 100 and 10,000 per square centimeter, depending upon the sample. Wafers had n-type conductivity with a concentration N_{d}−Nₐ of between 5 and 9×10¹⁸ per cubic centimeter. The wafers were used as substrates for device fabrication, particularly for GaN/AlGaN multi-layer device structures grown by the MOCVD process. Pn diodes were fabricated using a vertical current flow geometry, which was possible due to the good electrical conductivity of the GaN substrates.

According to an alternative embodiment, a reactor can be configured to fabricate multiple Group III nitride semiconductor devices on different substrates during a single reactor run in a manner that advantageously results in all of the Group III nitride structures being substantially uniform. In addition to growing epitaxial materials with uniform properties, they can be grown on large area substrates (e.g., at least 3 inches in diameter). Wafer uniformity can be achieved for thicknesses, doping and other properties. Wafer uniformity can be achieved by independently controlling gas delivery blocks to generate uniform gas flows and the base that supports multiple substrates to enable identical or substantially identical materials to be grown on large area substrates. Thus, embodiments of the invention provide significant improvements in processing and efficiencies and can generate wafers having a larger size than known systems. Embodiments can be used to grow multi-layer device structures on multiple wafers in the same epitaxial run, for example LED or transistor structures.

Alternative embodiments of the invention are directed to epitaxially growing layers of Group III nitride materials rather than bulk materials as described above with reference to FIGS. 1-8. With alternative embodiments, multiple, uniform devices and/or materials can be grown during a single run of a HVPE reactor and on larger substrates, thereby increasing the quality and consistency of the grown materials and yields.

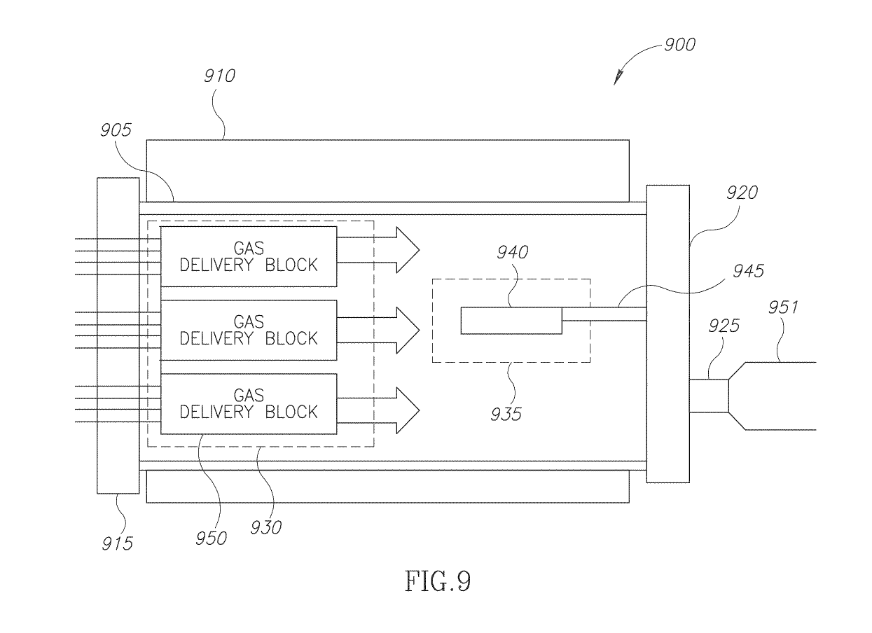

Referring to FIG. 9, one embodiment of a suitable HVPE reactor for providing uniform growth on large area substrates. Uniform growth of Group III nitride semiconductor structures can advantageously be achieved by forming a uniform gas components mixture in the growth zone over the growing surface. According to one embodiment, all of the gas components of a gas supply system are mixed together in the growth zone. To provide uniform and similar gas surroundings over multiple growing samples, the gas delivery system provides independent gas control for all delivered gas reagents. The gas flow in each gas delivery block is controlled independently of the other gas flows from other gas delivery blocks. Further, the substrate holder can be positioned to provide uniform chemical composition and flow velocity of gas reagents over growing samples for all samples located in the growth zone. In other words, embodiments of the invention advantageously allow each growing sample to contact gas flow having the same chemical composition and flow velocity, thereby allowing uniform samples to be grown during a single epitaxial run. Accordingly, embodiments provide significant improvements over known systems and methods that do not provide these capabilities and uniform growth.

More specifically, the HVPE reactor 900 includes a horizontal main reactor chamber 905, a resistively heated furnace 910, an inlet flange 915, an outlet flange 920, a gas exhaust 925 a source zone 930 and a growth zone 935. The reactor 900 also includes a substrate holder or base 940 for holding multiple substrates, a rod 945, e.g., a quartz rod, for controlling the movement of the substrate holder 940 and substrates into and out of the reactor chamber. The source zone 930 is located inside the reactor chamber 905 and includes a gas supply system 950 for providing gases comprising, by way of example, Ga, Al, In, and doping material. According to one embodiment, the gas supply system includes at least two gas delivery blocks. For purposes of explanation and illustration, not limitation, this specification refers to gas delivery blocks. For example, FIG. 9 illustrates three gas delivery blocks 950. Other numbers of gas delivery blocks 950 can also be used, such as four, five and six delivery blocks 950. The number of delivery gas blocks 950 can vary depending on the reactor configuration and application. Block arrows in FIG. 9 and in other figures schematically represent gas flow provided by the gas blocks.

The reactor shown in FIG. 9 can be made by modifying the reactor shown in FIG. 1. For example, the reactor shown in FIG. 1 can be modified by configuring the reactor to include and control multiple gas delivery blocks. Further, the substrate holder can be modified as necessary. The substrate holder or pedestal shown in FIG. 1, similar to the substrate shown in FIG. 9, can hold multiple substrates, which are loaded in the reactor for co-processing. It is understood that embodiments are not limited to this particular furnace configuration as other configurations (e.g., vertical furnaces) that offer the required control over the temperature, temperature zone or zones, gas flow, source and substrate location, source configuration, etc., can also be used. Further, the main reactor chamber can be configured with different furnace or heating zones (e.g., six zone furnace, eight zone furnace, split furnace, fast cooling furnace), and different flange designs can be used, such as air and water cooled. Thus, the component and arrangements of components shown in FIGS. 1 and 9 are not intended to be limiting.

Substrate holders can hold various numbers of substrates, e.g., 2-28 substrates. Further, the sizes of substrates can vary. For example, substrates can be 2″ substrates or they can be large area substrates having diameters of about 3-12″. Embodiments of the invention advantageously provide for uniform growth on large area substrates and, in addition, uniform growth for multiple wafers.

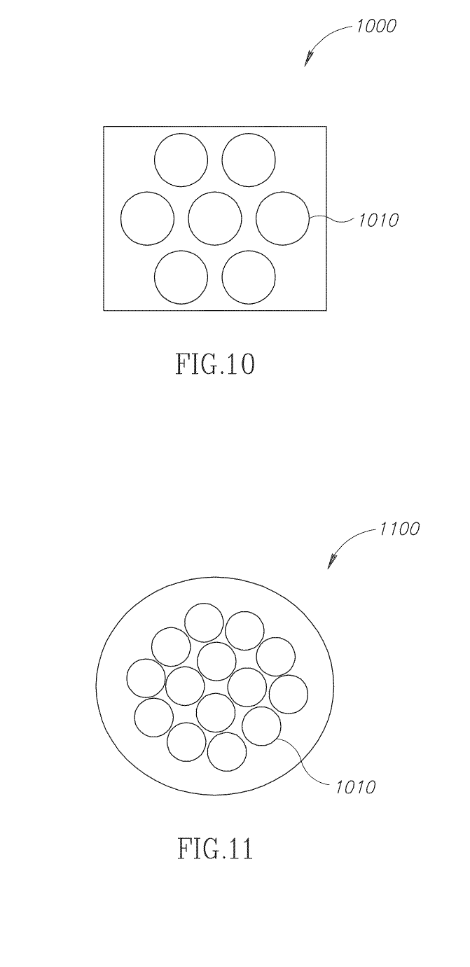

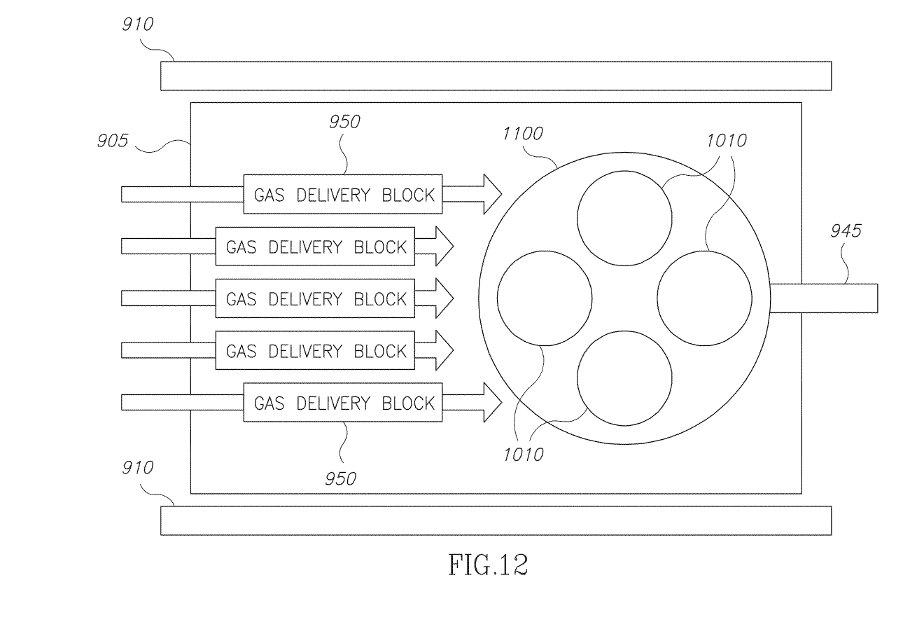

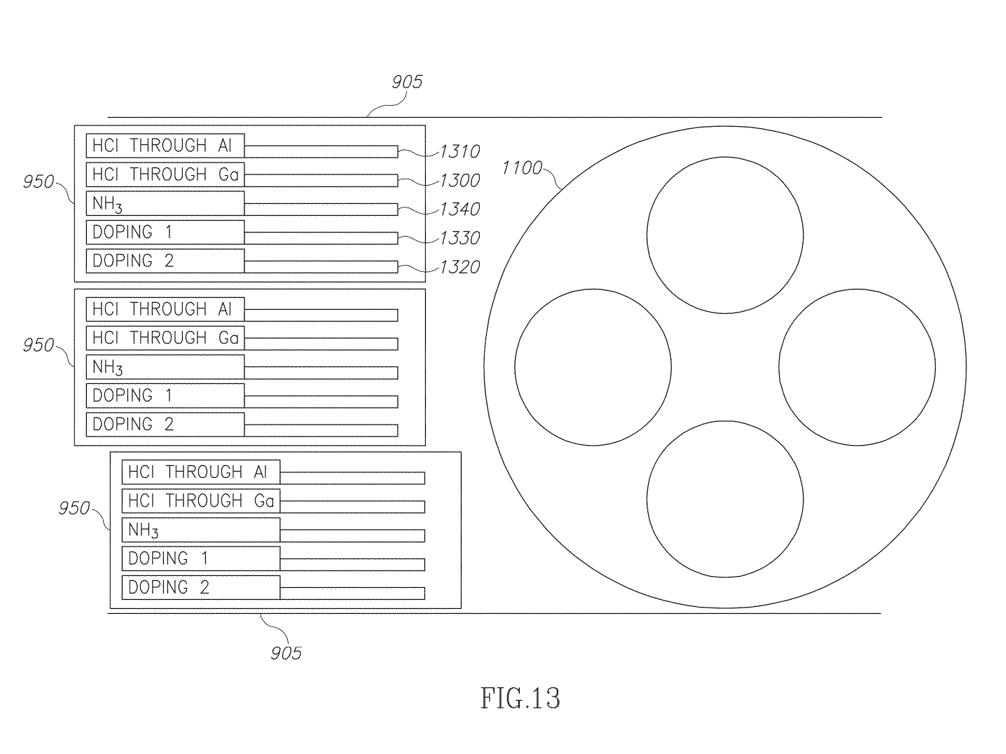

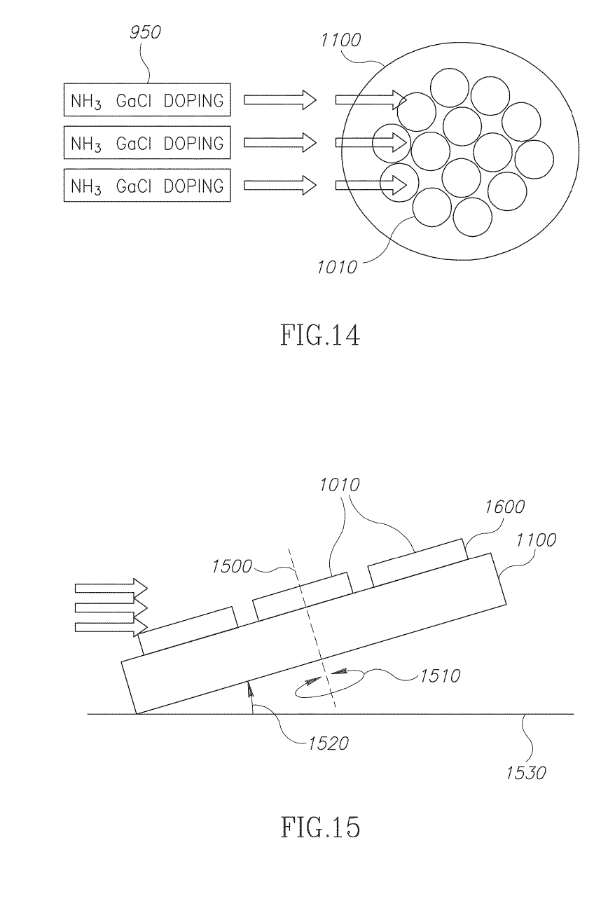

Suitable substrate holders that can be used with embodiments of the invention are shown in FIGS. 10 and 11. FIG. 10 illustrates a square substrate holder 1000 that can hold seven substrates 1010. FIG. 11 illustrates a circular substrate holder 1100 that can hold 14 substrates 1010. For purposes of explanation, not limitation, this specification refers to circular substrate holders 1100, as shown in FIG. 11. Other substrate holder shapes and sizes can be utilized as necessary. Alternative embodiments can be configured so that substrate holders support other numbers of substrates. Further, various substrate materials can be utilized with embodiments of the invention, including Si, sapphire, AlN, GaN, GaAs, quartz and SiC substrates. Referring to FIGS. 9 and 12-14, one suitable HVPE reactor 900 includes multiple gas delivery blocks 950. FIG. 12 illustrates five gas delivery blocks 950 as an example.

Referring to FIG. 13, each gas delivery block 950 includes independently controlled Ga, Al, NH₃, Ar, and doping source or inlet tubes. Each gas tube has an independent mass flow controller to regulate gas flows. Metal sources (boats with Ga, Al, metals) are located inside gas delivery blocks. Gas delivery blocks can also include In inlet tubes for growth of other Group III nitride structures. Metal source temperatures range from, e.g., about 350-850° C. One zone in the HVPE reactor is the source zone and another is the growth zone. The maximum growth zone temperature is about 1200° C.

As shown in FIG. 13, according to one embodiment, each gas delivery block 950 includes a Gallium source channel or tube 1300, an Aluminum source channel or tube 1310, one or more doping channels or tubes 1320 and 1330, and an ammonia channel or tube 1340. Additional components, such as separate Argon gas delivery tubes, HCl tubes, and additional NH₃ additional tubes and back flow tubes are known and are not shown in FIGS. 9, 12 and 13. The gas delivery blocks 950 can be positioned and configured so that the distance between gas delivery tubes of the blocks 950 is about 0.1 mm to a few centimeters, the diameter of the gas delivery tubes is about 1-50 and the distance between gas delivery blocks 950 is about a millimeters to a few centimeters.

For example, by controlling gas flow values for each individual gas lie or tube, uniform gas composition and flow velocity are provided for each growing sample. The gas flow values, e.g., gas flow volume or rate, through similar channels of various gas delivery blocks can be the same or may be different. For example, with three gas delivery blocks that operate during a GaN deposition process, HCl gas flows through three Ga source tubes at about 0.2 liter per minutes, 0.1 liter per minute, and 0.2 liter per minute, respectively. The gas blocks are typically located on the same level, but may be located using multi lever design.

As a further example, the distance between gas delivery tube 950 and substrate holder 1100 can range from about 1 mm to about 100 cm, preferably about 1-30 cm. Gas flow values can be from about 0.1 ccm to 20 slm. The multiple gas delivery block 950 configuration shown in FIGS. 9 and 12-14 allows for gas transport patterns that result in a uniform gas environment in the growth zone to produce uniform epitaxial material on large area substrates and on a multiple substrates in a single epitaxial growth run.

Thus, for each growth zone size and geometry, the position of the gas delivery blocks, e.g., relative distance between gas tubes and their directions, gas flow values are optimized to produce uniform gas composition and flow velocity at growing surface for each sample in located in the growth zone.

Uniform growth of Group III nitride semiconductor structures, such as GaN and AlGaN layers, can be obtained by adjusting the design, e.g., size, of the growth zone and growth parameters, such as gas flow, gas pattern and temperature distribution. Temperature profile is controlled by controlling heating elements of the furnace. Gas flows are controlled by mass flow controllers that are introduced in each gas lines. Gas patterns are controlled by the geometry of gas the delivery blocks, the geometry of the substrate holder, and the gas flow values through each tube. For example, chaining of the cross sectional areas of growth cells formed by substrate holder plates changes the gas velocity over the growing surface. The height of the rectangular cross-section of the growth cell can be varied from 3 to 0.5 cm, and a boundary layer thickness and partial pressure of active reagents can be adjusted in order to achieve growth rate and deposition uniformity. For example, GaCl and NH₃ gases can be mixed in the growth zone before they reach the multi-wafer susceptor. In this case, a homogeneous mixture of the reagents is created in the gas injection block, which is supplied to the growth block to provide uniform growth capabilities.

Referring to FIG. 15, in addition to controlling the gas delivery blocks 950, the substrate holders 1100 can also be controlled. For example, the substrate holder that supports a plurality of substrates 1010 can be rotated about an axis 1500 (represented by arrow 1510), tilted (represented by arrow 1520), and both rotated and tilted. As shown in FIG. 15, the substrate holder 1100 can be rotated about an axis 1500 at a rate of about 0.1 to 100 rpm. Rotating the holder 1100 and substrates 1010 supported thereby can produce epitaxial materials having uniform thickness, doping, optical, and electrical properties.

By tilting the substrate holder 1100 to arrange the substrates 1010 at an angle relative to the horizontal 1530, the gas flows from the gas delivery blocks 950 that are mixed and introduced into the growth zone are directed at the substrates 1010 at an angle 1520. According to one embodiment, as shown in FIG. 15, the gas flows are generally parallel to the horizontal 1530, and the substrate holder 1100 is tilted so that the angle between the gas flows and the substrates 1010 is about 0.5 degree to about 90 degrees, preferably about 1-30 degrees, preferably between about 1 and 10 degrees. Tilting the substrate holder can prevent non-uniform growth that is caused by gas mixture composition depletion while moving along the growth zone. The degree of tilting can be adjusted as needed to achieve uniform growth and to reduce defect density.

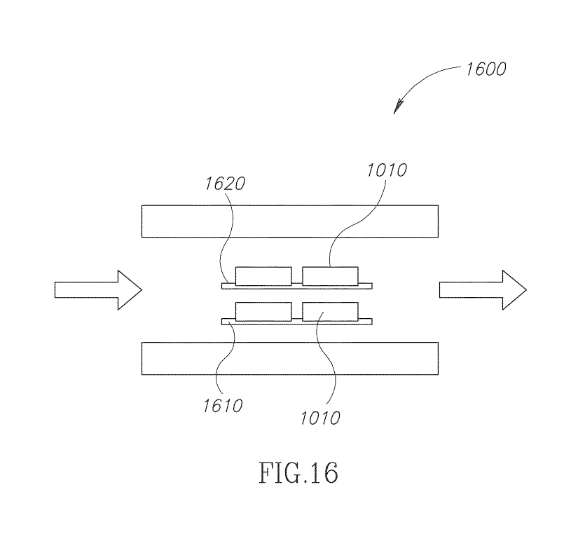

Referring to FIGS. 16-18, in alternative embodiments of the invention, a reactor includes a multi-level substrate holder rather than a single level substrate holder as shown in FIGS. 10-12 and 14. A multi-level substrate holder can substantially increases processing capacity. For example, processing capacity can be increased when using a two-level substrate holder in which each level can support, for example, six substrates, resulting in fabrication of 12 wafers in a single epitaxial run. Capacity increases can be multiplied depending on the number of levels a substrate holder has.

Referring to FIG. 16, according to one embodiment, a multi-level substrate holder 1600 has two levels—a lower level 1610 and an upper level 1620. A substrate holder 1600 can include other numbers of levels, e.g., three, four, five and so on with appropriate reactor and growth zone adjustments depending on processing capacity. For purposes of illustration and explanation, not limitation, this specification refers to a two-level substrate holder 1600 or, alternatively, two separate substrate holders stacked on top of each other. Further, persons skilled in the art will appreciate that a multi-level substrate holder can be a single substrate holder having multiple levels or multiple individual substrate holders. This specification refers to a multi-level substrate holder for purposes of explanation, not limitation.

In the embodiment illustrated in FIG. 16, both levels 1610 and 1620 support at least one substrate 1010. Further, in the illustrated embodiment, both levels 1610 and 1620 are arranged so that all of the substrates 1010 are face up and face the same direction. As a result, the material growth on the substrates 1010 occurs in the same direction. When a multi-level substrate holder 1600 in this configuration is utilized, the gas delivery blocks 950 can be located on one level or on two different levels so that the gas flows from the blocks 950 can be appropriately adjusted for different levels. The substrates 1010 can be offset relative to each other or vertically aligned with each other (i.e., one substrate is directly above another substrate).

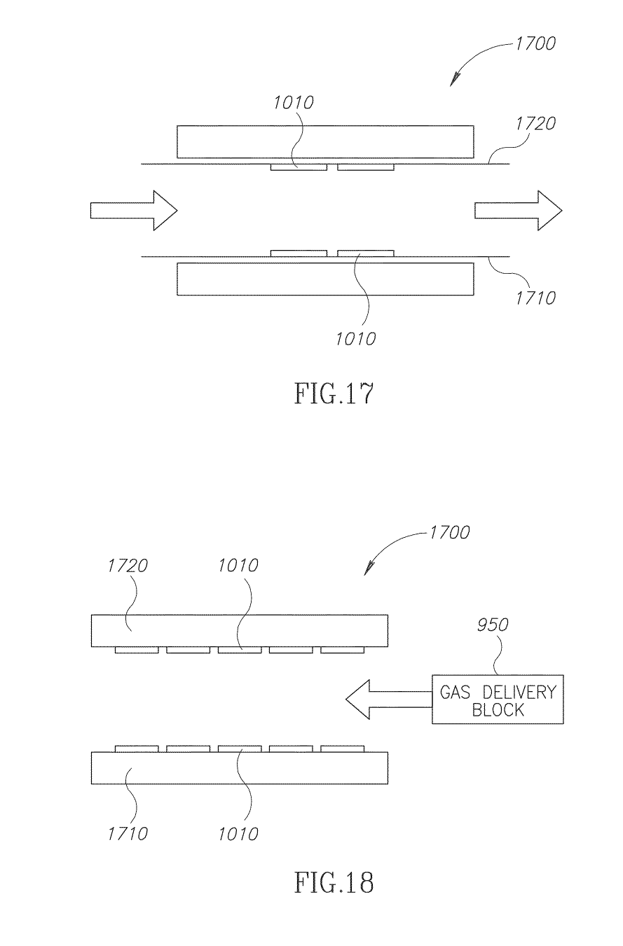

Referring to FIGS. 17 and 18, according to another embodiment, a multi-level substrate holder 1700 includes lower and upper levels 1710 and 1720, similar to the holder 1600 shown in FIG. 16. However, in the embodiment illustrated in FIG. 17, the levels are configured so that the upper level 1720 supports a substrate 1010 that is face down, and the lower level 1710 supports a substrate 1010 that is face up. As shown in FIG. 18, the gas delivery blocks 950 can be positioned so that the gas flows from the blocks 950 are directed between the lower and upper levels 1710 and 1720.

The substrates, therefore, face opposite directions, and the material growth will also occur in opposite directions. More specifically, growth will occur on the lower level substrate in an upward direction, and growth will occur on the upper level substrate in a downward direction. The substrates may be offset relative to each other or a substrate may be directly above another substrate, as shown in FIGS. 17 and 18. The opposite facing arrangement shown in FIGS. 17 and 18 can be advantageous since using substrates that are face-down reduces and/or eliminates defects that result from solid particles dropping down onto grown surfaces.

Referring to FIG. 19, embodiments of the invention can be used to fabricate a Group III nitride semiconductor structure on a large area substrate, e.g., a 4″ or larger diameter substrate. For example, according to one embodiment, a GaN layer having a thickness of about 15 microns is grown on a 4″ diameter substrate. Tests on this material growth were performed and confirm that the thickness of the GaN material varied by less than about 1% over the wafer diameter. The substrate can have a diameter of 2-12″, and the grown group III nitride layers can have a thickness of about 0.1 microns and larger, for example, 1 mm.

According to another embodiment, HVPE growth as described above can be used to fabricate multi-layer device structures, such as High Electron Mobility Transistors (HEMTs), blue and Ultraviolet (UV) LEDs, nitride laser diodes (LDs) and other similar devices, on a large area substrate, e.g., a substrate having a diameter of about 3-8″. These device structures can be grown with or without thick (e.g., >10 microns, >20 microns, >30 microns) nitride layers, such as GaN, AlN, AlGaN, InGaAlN layers that are grown before the device structure in the same epitaxial run. Thick nitride layers, however, may be useful for reducing defect density in the device layers and to improve device performance by reducing degradation.

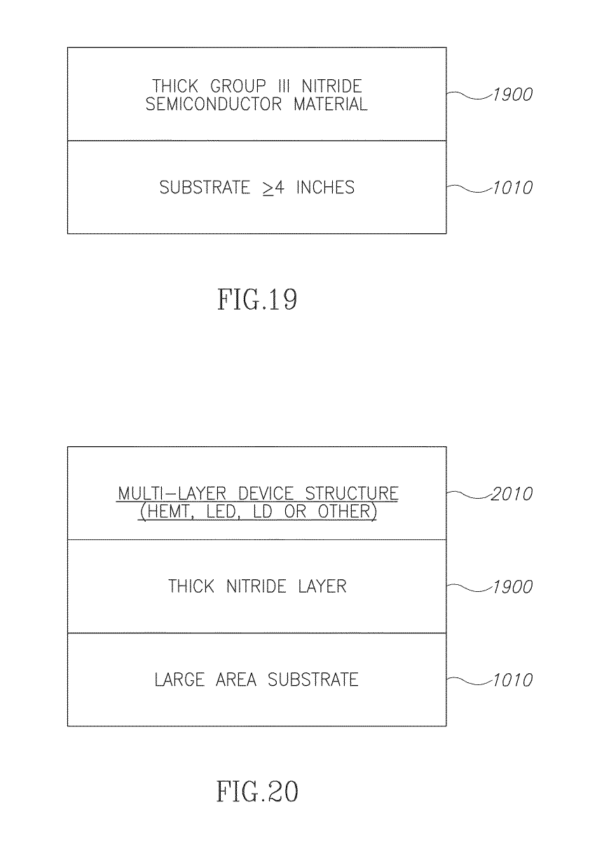

For example, referring to FIG. 20, an epitaxial wafer grown with the HVPE apparatus and method embodiments described above is a large area (3-6″ and larger) substrate 1010, a thick nitride layer 1900 grown on the substrate 1010, and a device structure 2010 grown on the thick nitride layer 1900. The nitride layer 1900 has a thickness of about 10-20 microns and thicker. The nitride layer 1900 is a low defect, uniform and crack free layer that improves device performance.

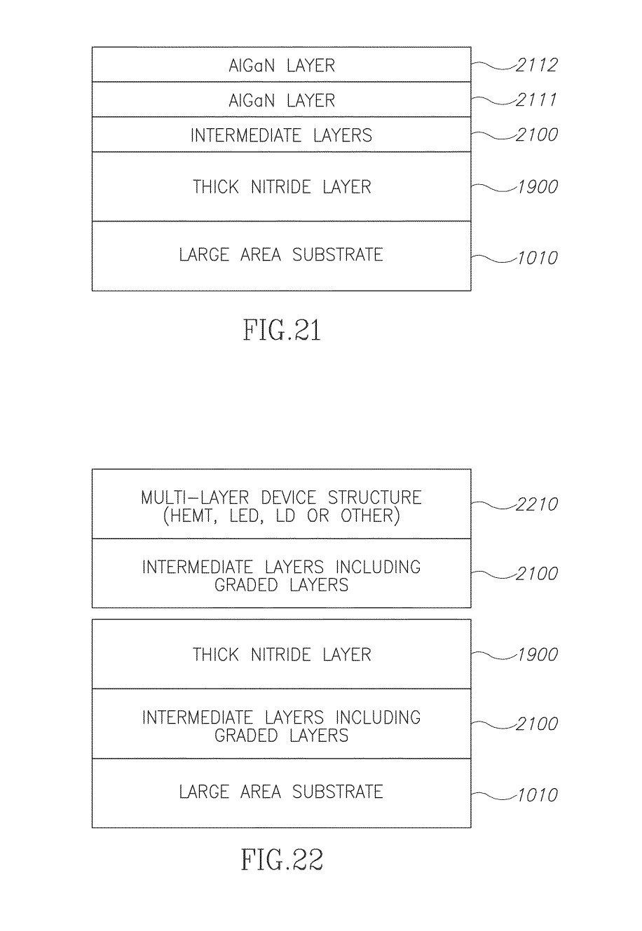

Referring to FIG. 21, Group III nitride semiconductor structures can also be grown using with apparatus and process embodiments using one or more buffer or intermediate layers in between the substrate and the thick layers. In the illustrated embodiment, a thick nitride layer 1900 is grown on a large area substrate 1010, and an intermediate or buffer layer 2100 is grown on the thick nitride layer 1900.

The intermediate layer 2100 may be formed of double AlGaN layers 2111 and 2112, as shown in FIG. 21. The intermediate layer can also include graded (AlGaN, InGaAlN) layers. In the illustrated embodiment, the device multilayer epitaxial structure is as AlGaN/AlGaN double-layer structure in which both AlGaN layers have an AlN concentration ranging from 0 to 100 mol % of AlN and different or the same compositions and doping. Both of the AlGaN layers can have p-type conductivity, or n-type conductivity, or have different types of conductivity, forming a pn junction, I-n junction, p-I junction (wherein I-type is electrically insulating material).

FIG. 22 illustrates another manner of fabricating multi-layer device structures 2210, such as HEMTs, LEDs, and LDs on a large area substrate 1010 according to a further embodiment of the invention. In the illustrated embodiment, one or more intermediate layers 2100 (as described above with respect to FIG. 21) are grown on a large area substrate 1010. A thick nitride layer 2000 is grown on the intermediate layers 2100. Further top intermediate layers 2100 are grown on the thick nitride layer 2000, and a multi-layer device 2210 is grown on the top intermediate layers 2100.

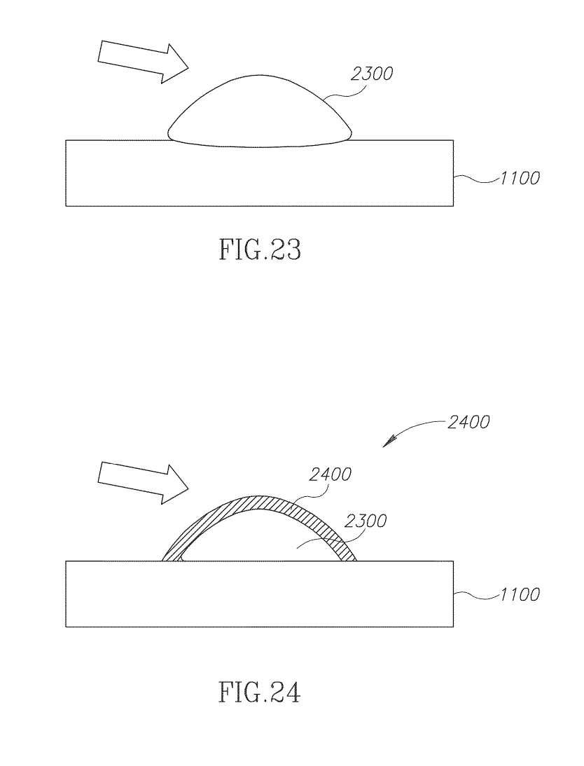

Referring to FIGS. 23 and 24, according to a further alternative embodiment, uniform GaN (and AlGaN) layers and multi-layer epitaxial structures can be grown on a flat substrate (as shown in FIGS. 10 and 11) and on non-flat substrate 2300, as shown in FIG. 23. According to one embodiment, as shown in FIG. 23, the non-flat substrate 2300 is convex. Further, as shown in FIG. 24, the resulting Group III nitride structure 2400 that is grown on the convex substrate is also convex.

In the embodiments described with respect to FIGS. 9-24, the gas flows, temperature distribution, growth zone geometry, and sample rotation, are controlled to produce uniform high quality crack free layers having a thickness of about 10 microns and greater on the dome substrates. In producing these structures, the AlN concentration in the layers was controlled from 0 to 100 mol. %. AlGaN layers with AlN concentration was about 30 mol. %, 60 mol., and 80 mol. % were grown. AlN concentration in AlGaN layers was controlled by controlling the ratio of Ga chloride containing flow to Al chloride containing flow in the growth zone. AlN layers up to 50 micron thick without cracks were grown on 4 inch diameter substrates. (SiC, sapphire, Si, quarts, and others). As in other embodiment of the invention, the substrate temperature is from 600 to 1200° C., with the preferred substrate temperature from 900 to 1050° C.

Referring again to FIG. 9, according to another embodiment of the invention, the reactor is equipped with an environmental pollution system 951. According to one embodiment, the pollution system is an air scrubbing system. The air scrubbing system effectively removes hazardous component and solid particles from the HVPE reactor exhaust released through the outlet and allows the HVPE reactor to operate for extended durations, e.g., 50 hours, in stable growth conditions.

According to one embodiment, the air scrubbing system includes a connected wet scrubber and a wet Electrostatic Precipitator (ESP), arranged in this sequential order. The wet scrubber and ESP units can be free-standing units that are connected by a gas pipe. Alternatively, the units can be combined into one unit, e.g., the ESP can be placed on top of the wet scrubber. The scrubbing liquid is preferably water that is circulated in the wet scrubber and ESP. The pH value of the water is adjusted to an level that is appropriate for discharge into a sewer.

The operating parameters of the air scrubbing system are preferably such that air flow capacity is about 50-5,000 ACFM for removing at least 99% of HCL and Ammonia gases, and at least 99.9% of solid particles can be removed. The system be used with concentrations of gases from the reactor exhaust but before the air pollution system inlet being up to 15800 PPM for Ammonia, up to 6600 PPM for HCl, and up to 2.8 GR/ACFM for solid particles. Up to 100% of solid particles can be represented by Ammonia Chloride and size of particles is about 0.1-3.0 microns.

Persons skilled in the art will readily appreciate the numerous benefits of embodiments of the invention. Multiple high quality GaN, AlGaN and other Group III nitride epitaxial wafers can be grown in a uniform manner and during a single epitaxial run. These wafers are particularly useful in the development and realization of advanced electronic components for various applications, including radar, communications, and UV optoelectronics (emitters and sensors) and military applications, such as multifunction RF systems, radar, electronic surveillance, high-speed communications, electronic warfare, and smart weapons. Further, nitride devices grown with embodiments of the invention significantly improve power capabilities, reduction of on- and off-state losses, noise immunity, safe operating area, and switching speed of power semiconductor electronics. Thus, embodiments of the invention are particularly advantageous compared to known HVPE and MOCVD processes and reactors in terms of uniform growth, growth size and capabilities on larger area substrates, cost, reliability, reproducibility, and growth rates and yield by using multi-level substrate holders.

The inventors believe that these capabilities have not heretofore been successfully demonstrated. These advantages and improvements over known HVPE systems and growth methods are summarized below.

### Growth Procedure and Material Characterization

Certain aspects of the configuration of the HVPE reactor and its operation may be similar to the configuration and method described relative to FIGS. 1-8. However, a description of the configuration of a HVPE reactor and related method for epitaxial growth according to embodiments of the invention are provided. In various tests to demonstrate embodiments of the invention, an atmospheric-pressure horizontal hot-wall quartz HVPE reactors and two-zone resistively heated furnaces were utilized. The HVPE reactor includes a main quartz tube, inlet quartz gas tubes for metal sources, and a holder for substrates. The reactor also includes a multi-channel gas distribution/control system with mass flow controllers. Argon was used as a diluting gas and ammonia was used as an active nitrogen source. Ammonia and HCl were supplied from gas tanks, and boats containing metallic Ga (7N) and Al (5N) are placed into quartz tubes.

During epitaxial GaN growth, HCl was passed through the Ga source channel. GaCl gas was formed by a reaction of metallic Ga and HCl. The GaCl gas was transported from the source zone to the growth zone by Argon flow. When growing AlGaN solid solutions, an additional HCl stream was passed through the Al source channel to react with metallic Al forming AlCl₃. These reagents were mixed in the growth zone and reacted with ammonia forming GaN or Al₁₋ₓGa_{xN} epitaxial layers.

In these tests, sapphire wafers were used as substrates. GaN and AlGaN layers were deposited on the (0001) plane of the substrates. After cleaning, the HVPE reactor was purged by Ar to remove residual oxygen, and the substrates were loaded into the reactor. Growth was initiated by flowing NH₃ and HCl through the reactor. In some experiments Si doping of GaN layers was performed.

Multi-Wafer HVPE Growth Certain tests demonstrated the ability to grow multiple Group III nitride wafers during a single HVPE run. FIGS. 9-12 illustrate substrate holders for holding multiple substrates and a growth zone for a horizontal HVPE reactor.

Two 2″ wafers were located on a single quartz substrate holder. Growth occurred on the top surface of the substrates. GaN and AlGaN layers were grown on multiple substrates at a growth rate of about 1 micron per minute.

### Inverted HVPE Growth

Other tests demonstrated growth of GaN and AlGaN layers in HVPE reactor demonstrated on a inverted substrate, i.e., on a face down substrate rather than a face up substrate. Two substrate holders are used to test inverted growth. One substrate holder was configured such that the substrate is fixed by two quartz posts that are welded to a quartz plate. Another substrate holder was located inside a circular window that was machined in a quartz plate.

These substrate holders were tested by introducing them inside an HVPE growth reactors. AlGaN and GaN layers were grown on 2-inch diameter sapphire substrates using standard HVPE growth procedure. These tests demonstrated that AlGaN and GaN epitaxial layers can be grown from substrates that are face up and from substrates that are face down in a ceiling position

Multi-Level Multi-Wafer HVPE Growth Further tests were conducted using multi-level substrate holders, e.g., as shown in FIGS. 16-18. A multi-level substrate holder that supports all substrates facing upwardly was fabricated and capable of holding four 2″ substrates to grow eight wafers. A two-level holder was made using two quartz plates, each capable of holding two 2″ substrates. This holder was introduced into the HVPE reactor and GaN and AlGaN layers were grown in two different growth runs. Embodiments demonstrated that processing capacity can be multiplied by using multiple levels. The uniformity of the resulting structures was improved in other tests, as discussed below.

### Multi-Wafer HVPE Growth with Enlarged Growth Zone

Further tests of multi-level growth were conducted using an enlarged growth zone, which allowed a larger substrate to be inserted into the reactor. The substrate holder that was a two-level substrate holder, each level capable of supporting seven substrates, as shown in FIG. 10. Thus, the substrate holder is capable of supporting 14 2″ substrates.

The growth zone had dimensions of about 50×20×5 cm or lager, for example, 70×30×10 cm. The growth zone was located inside the horizontal reactor chamber or tube that includes end flanges for loading the substrate holder and source materials, including at least one group III metal source. With a multi-level substrate holder, the spacing between substrate holding plates ranged from about 1 mm to 10 cm. The multi-level substrate holder included east two plates. Certain designs involved more than 7 plates or levels. The plates can be tilted relative to the gas flow direction and the tilt angle for each plate can be controlled or changed independently of the other plates. Thus, for one substrate holder, there can be different plates at different tilt angles.

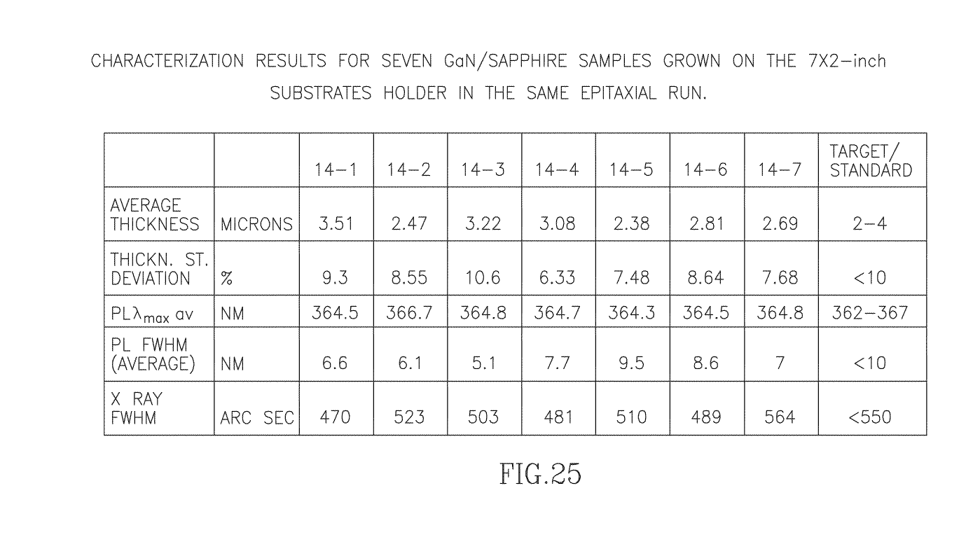

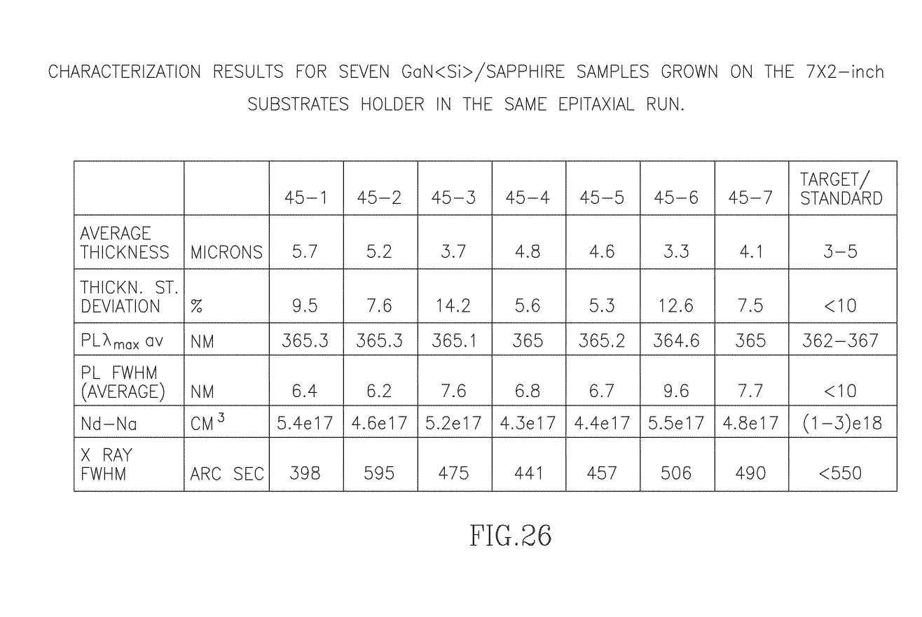

Two separate growth runs were performed using the 7×2 substrate holder. One run involved growing seven undoped GaN layers in a single growth run. Another run involved growing seven GaN layers that were doped with Si in another single run. Results of these tests are summarized in FIGS. 25 and 26.

Referring to FIGS. 25 and 26, most of the GaN and doped GaN layers that were grown on the 7×2-inch holder displayed thickness variations having a standard deviation less than 10% except for one undoped GaN sample and two Si-doped GaN samples. X-ray rocking curve FWHM values for these samples are also less than 550 arc sec, except for one GaN sample and one doped GaN sample.

Thus, the test results demonstrate that embodiments of the invention provide improvements over known HVPE reactors by fabricating multiple wafers in a single run, and the fabricated wafers exhibited substantial uniformity from wafer to wafer. This is particularly beneficial since processing capacities can be substantially increased while maintaining uniform growth characteristics.

The inventors believe that this test is the first successful demonstration of 7×2″ HVPE growth of Group III nitride semiconductor structures. Uniformity of the layers can be improved by rotating the substrate holder. Flow and temperature distribution in a multi-wafer growth zone are factors for designing a rotating substrate holder capable of holding various number of wafers, e.g., 7×2″ to 28×2″ growth capacities.

To demonstrate 28×2″ HVPE process, the growth reactor configuration is appropriately modified by modifying the substrate holder, heating elements, internal quartz ware, gas delivery system, and gas mixing zone. Growth zone geometry and gas distribution modeling was performed. Uniformity of the growth materials can be adjusted by using multiple gas delivery blocks with independent gas flow control.

### GaN Growth on Large Area Substrate

The HVPE reactor shown in FIG. 9 was also used to grow Group III nitride semiconductor structures with an enlarged growth zone to deposit GaN layers on sapphire substrates that are larger than substrates used in known reactors and processes. The inventors believe that growth of GaN layers on a 4″ substrate using a HVPE reactor was demonstrated for the first time. The thickness of the GaN layer was about 5 microns.

The tests demonstrate that HVPE growth of GaN and other Group III nitride semiconductor structures, such as AlGaN epitaxial layers, can be grown using embodiments of the invention. Furthermore, these results indicate that HVPE growth using larger substrates, e.g., 3-6″ and larger substrates, of GaN and AlGaN epitaxial layers can be performed. Further, such capabilities can be implemented using multi-level substrate holders in order to substantially increase yields during a single epitaxial run.

### Blue and UV LED Structure Growth on Large Area Substrates

Embodiments of the invention were further demonstrated by the growth of blue and UV LED structures on multiple 6″ and 8″ sapphire and Si substrates during a single epitaxial run in the HVPE reactor. The growth was conducted on two, three and four level substrate holders. Each substrate level can hold two or more large area substrates. The light emitted region of UV LEDs was fabricated from AlGaN (undoped or n-type doped), and the light emitting layer of the blue LEDs was GaN or InGaN. The blue and UV LED structures that were grown exhibited uniform materials properties.

The multi-layer LED structure emissions were at a peak wavelength of about 265 nm to about 490 nm for different structures. The standard deviation of the thickness of the structures was less than 25%, typically less than 10%. Further, the standard deviation of the compositions of the separated alloy layers inside the LED structures was less than 12%, typically less than 5%.

### HEMT Structure Growth on Multiple Large Area Substrates

Embodiments of the invention were also used to grow AlGaN/GaN-based high electron mobility transistor HEMT structures on multiple large area 8″ Si wafers in a single epitaxial HVPE run. Another test was run to grow six HEMT epitaxial wafers on 3″ 6H—SiC substrates. During these tests, the thicknesses of the AlN or GaN layers ranged from about 0.1-100 microns. The epitaxial structures exhibited no cracks. The standard deviation of the thickness of the layers of these large area epitaxial wafers was less than 20%, typically less than 10%, and less than 5% in some structures.

### AlN Growth on Multiple Large Area Substrates

Embodiments of the invention were also used to grow AlN epitaxial layers on 4″ large area substrates using a two level substrate holder. The substrates were (0001) c-plane 3-degree off-angle sapphire wafers with one side being prepared for epitaxial growth.

Six 4″ substrates were loaded onto a two-level substrate holder. Each level of the substrate holder supported three 4″ substrates. In this test, the substrates were loaded in a face-down position, e.g., as shown in FIG. 18. The growth apparatus included two independently controlled gas delivery blocks, each block having an ammonia gas line, an Al source line and an Ar gas line. The gas flow from each line was controlled by separate mass flow controllers. The gas flow rates ranged from about 0.05 to 10 liters per minute for different gas delivery tubes. The gas delivery tubes were placed in the main reactor chamber with a spacing between tubes ranged from a few millimeters to several centimeters providing a uniform gas flow pattern in the growth zone. The gas flows were calibrated for each mass flow controller to make uniform deposition of AlN on large area 4″ substrates. In order to improve uniformity further, the substrate holder plates were positioned at an angle of about 0.1 to about 10 degrees relative to the gas flows.

For these tests, Al metal was placed into sapphire boats, which were placed into Al source tubes of two gas delivery blocks. The substrate holder was loaded into the reactor and sealed. The reactor and each gas line were purged by flashing Ar gas through the tubes. The furnace was heated. The Al source temperature ranged from 500-800° C., and the substrate temperature was about 1020-1030° C. Before growth, the substrates were treated at growth temperature by being annealed for 30 minutes in a mixture of Ar and ammonia. During treatment, the gas flows ranged from about 0.01-10 liters per minute. Growth was initiated by flowing HCl gas through Al source tubes in both gas delivery blocks. The reaction between Al metal and HCl gas resulted in the formation of aluminum chloride gas, which was transported by Ar gas into the growth zone. Both gas delivery blocks were operating simultaneously. The growth time was about two minutes and was terminated by switching off the HCl gas flows through the Al source tubes. Ammonia gas flows were also terminated after about five minutes. The samples that were grown were cooled in Ar gas, and the six grown samples were unloaded from the multi-level sample holder.

The AlN layers that were grown were characterized by optical and electron microscopy, atomic force microscopy, optical transmission, and x-ray diffraction. Using optical microscopy, the thickness of AlN layers ranged from about 0.4-0.5 microns. The standard deviation of the thickness for the grown layers was less than 9% for each sample, typically less than 5%, and less than 1% for the best samples. The standard deviation of the thickness deviation for the six grown samples on different wafers was less than 30%. The full width at half maximum of X-ray diffraction rocking curves was less than 300 arc sec and less than 700 arc sec for the (002) and (102) peaks, respectively. The standard deviation of the FWHM values of the rocking curves for each sample was less than 10%. The surface roughness (rms) for the grown layers ranged from about 4-6 nm as measured by atomic force microscope using 5 μm×5 μm scans. The electrical resistivity of the grown AlN layers was about 10¹⁰ Ohm cm at room temperatures. The layers had good optical transparency in the UV and visible spectrums. The optical transparency was about 90% at a wavelength of 230 nm.

### AlGaN/GaN Growth on Multiple Large Area Substrates

Embodiments of the invention were further demonstrated by growing AlGaN/GaN epitaxial structures on multiple sapphire substrates in the same epitaxial run. The substrates had the (0001) C-pane 0.4 degree-off surface orientation. During these tests, 21 2″ diameter sapphire substrates were loaded into a three level substrate holder. Wafers were put in face-down position.

The growth reactor was equipped with three gas delivery blocks, each of which included a Ga source tube, an ammonia tube, an Ar gas tube, an n-type doping tube (Si or Ge doping), and a p-type doping tube (Mg or Zn sources).

The substrates were heated in Ag gas. The metal sources were heated to a temperature of about 300-860° C., and the substrates were heated to about 1040° C. The temperature difference from substrate to substrate was less than about 0.5° C. Growth was initiated by a deposition of AlGaN layer by activating HCl gas for the Al and Ga source tubes. Simultaneously, ammonia flows were activated. By providing ammonia, aluminum chloride and gallium chloride gases entered the growth zone. AlGaN layers were simultaneously grown on the 21 sapphire wafers. Growth was terminated by de-activating the HCl gas flows. The gas tubes were purged, and GaN growth was then initiated by flowing HCl gas through Ga source tubes. To finish growth, HCl and ammonia flows were de-activated, the samples were cooled to room temperature and unloaded from the multi-level substrate holder. Thus, embodiments of the invention were utilized to grow multiple AlGaN/GaN hetero-structures in the same epitaxial run.

This process was repeated with different durations of AlGaN and GaN layer growth. In some processes, n-type or p-type doping was used to control GaN conductivity. The thickness of AlGaN and GaN layers grown in the various test runs ranged from about 0.001-2 and about 0.005-1000 microns, respectively. For wafers grown in the same HVPE run, the standard deviation of wafer thickness across wafer diameter was less than 10%, typically less than 5%. The standard deviation of wafer-to-wafer thickness was less than 16%, typically less than 10%. The GaN layers showed atomic carbon background impurity concentration less than 10¹⁶ cm⁻³ and atomic oxygen background impurity concentration less than 10¹⁷ cm⁻³. The standard deviation of doping for grown GaN layers was less than 100%, typically less than 20%. The X-ray diffraction rocking curve for undoped GaN layers was narrower than 300 arc sec and 500 arc sec for (002) and (102) peaks, respectively. The standard deviation of wafer composition was less than 25% from wafer to wafer, typically less than 10%.

Thus, embodiments provide significant advantages over known systems in by significantly increasing yields and reducing costs, while maintaining substantial wafer to wafer uniformity, thereby improving development and production of various electronic components, such as high-power/high-frequency electronics and UV optoelectronics, including sensors and components for space communications.

As will be understood by those familiar with the art, the present invention may be embodied in other specific forms without departing from the spirit or essential characteristics thereof. Accordingly, the disclosures and descriptions herein are intended to be illustrative, but not limiting, of the scope of embodiments of the invention, as set forth in the following claims.

1. (canceled)

2. A method of fabricating multiple Group III nitride semiconductor structures in a Hydride Vapor Phase Epitaxy (HVPE) reactor during a single epitaxial run, the method comprising:
positioning a plurality of substrates in a growth zone of a HVPE reactor;
heating the growth zone to a growth temperature;
providing same growth materials for growing Group III nitride semiconductor structures to the growth zone from each of a plurality of gas delivery blocks; and
independently controlling rates at which each gas delivery block delivers material to the growth zone so that each substrate is substantially simultaneously exposed to a substantially same composition of growth materials.

3. A method according to claim 2 and comprising placing the substrates on a surface of a same substrate holder.

4. A method according to claim 3 wherein the substrate holder surface is planar.

5. A method according to claim 3 wherein the substrate holder surface is convex.

6. A method according to claim 2 and comprising supporting the substrates on different substrate holders of a plurality of substrate holders.

7. A method according to claim 6 and comprising positioning the substrate holders along a stacking direction, one over the other.

8. A method according to claim 7 wherein supporting the substrates comprises supporting them so that they face in substantially opposite directions relative to the stacking direction.

9. A method according to claim 8 and comprising flowing the materials in a gaseous state along a direction substantially perpendicular to the stacking direction.

10. A method according to claim 7 wherein supporting the substrates comprises supporting them so that they face in a same direction relative to the stacking direction.

11. A method according to claim 10 and comprising flowing the materials in a gaseous state along a direction substantially perpendicular to the stacking direction.

12. A method according to claim 6 wherein a substrate holder surface is planar.

13. A method according to claim 6 wherein the substrate holder surface is convex.

14. A method according to claim 2 and comprising controlling the position of a substrate holder supporting a substrate to expose the substrates to the same composition of growth materials.

15. A method according to claim 14 wherein controlling the position comprises tilting the substrate holder.

16. A method according to claim 14 wherein controlling the position comprises rotating the substrate holder.

17. A method according to claim 14 and comprising controlling temperature to expose the substrates to the same composition of growth materials.

18. A method of fabricating multiple Group III nitride semiconductor structures in a Hydride Vapor Phase Epitaxy (HVPE) reactor during a single epitaxial run, the method comprising:
positioning substrates in a growth zone of the reactor so that they face in substantially opposite directions; and
flowing same growth materials for growing Group III nitride semiconductor structures to the growth zone so that the structures grow simultaneously in opposite directions.

19. An Hydride Vapor Phase Epitaxy (HVPE) reactor comprising:
a chamber having a growth zone for growing semiconductor structures;
a heater controllable to heat the growth zone to a growth temperature;
at least one substrate holder for holding substrates on which the semiconductor structures are grown; and
a plurality of gas delivery blocks, each configured to deliver same growth materials to the growth zone at independently controllable rates.
